(19) United States
(12) Patent Application Publication
(10) Pub. No.: US 2022/0308438 A1
(43) Pub. Date: Sep. 29, 2022

(54) METHOD FOR MANUFACTURING MULTILAYERED-REFLECTIVE-FILM-PROVIDED SUBSTRATE, REFLECTIVE MASK BLANK AND METHOD FOR MANUFACTURING THE SAME, AND METHOD FOR MANUFACTURING REFLECTIVE MASK

(71) Applicant: HOYA CORPORATION, Tokyo (JP)

(72) Inventors: Kentaro IWAMOTO, Tokyo (JP); Kazuhiro HAMAMOTO, Tokyo (JP)

(73) Assignee: HOYA CORPORATION, Tokyo (JP)

(21) Appl. No.: 17/683,110

(22) Filed: Feb. 28, 2022

(30) Foreign Application Priority Data
Mar. 24, 2021 (JP) 2021-050261
Feb. 24, 2022 (JP) 2022-026612

(51) Int. Cl. G03F 1/24; G03F 1/60; G03F 1/84; G03F 1/54

(52) U.S. Cl. CPC G03F 1/24; G03F 1/60; G03F 1/84; G03F 1/54

(57) ABSTRACT

A method for manufacturing a multilayered-reflective-film-provided substrate including a substrate and a multilayer reflective film that reflects EUV light on the substrate, the method includes performing a first defect inspection on the multilayered-reflective-film-provided substrate with a first wavelength to acquire first defect information, performing a second defect inspection on the multilayered-reflective-film-provided substrate with a second wavelength different from the first wavelength to acquire second defect information, and determining whether there is an unmatching defect and a matching defect by comparing the first defect information with the second defect information to acquire third defect information.

### CROSS-REFERENCE TO RELATED APPLICATIONS

This application claims priority to Japanese Patent Application No. 2021-050261, filed on Mar. 24, 2021, and to Japanese Patent Application No. 2022-026612, filed Feb. 24, 2022, and the contents of which are incorporated by reference.

### BACKGROUND

### 1. Technical Field

The present disclosure relates to a reflective mask used for manufacturing a semiconductor device or the like, a reflective mask blank used for manufacturing a reflective mask and a method for manufacturing the reflective mask blank, and a method for manufacturing a multilayered-reflective-film-provided substrate used for manufacturing a reflective mask blank.

### 2. Description of the Related Art

In recent years, in the semiconductor industry, a fine pattern exceeding a transfer limit of conventional photolithography using ultraviolet light has been required as semiconductor devices are highly integrated. In order to enable such fine pattern formation, extreme ultra violet (hereinafter referred to as “EUV”) lithography, which is an exposure technique using EUV light, is promising. Here, EUV light refers to light in a wavelength range of a soft X-ray region or a vacuum ultraviolet region, and specifically is light having a wavelength of about 0.2 to 100 nm. A reflective mask has been proposed as a transfer mask used in this EUV lithography. In such a reflective mask, a multilayer reflective film that reflects exposure light is formed on a substrate, and an absorber film that absorbs exposure light is formed in a pattern on the multilayer reflective film.

The light incident on the reflective mask set in an exposure apparatus is absorbed in a portion with the absorber film, and is reflected by the multilayer reflective film in a portion without the absorber film. The reflected image is transferred onto a semiconductor substrate through the reflective optical system to form a mask pattern. As the multilayer reflective film, there is a known film in which Mo and Si each having a thickness of several nm are alternately laminated that, for example, reflects EUV light having a wavelength of 13 to 14 nm.

As a method for manufacturing such a reflective mask blank, WO 2014/129527 A discloses a method for manufacturing a reflective mask blank in which a multilayer reflective film that reflects EUV light is formed on a substrate and a laminated film is formed on the multilayer reflective film. Specifically, WO 2014/129527 A discloses that the manufacturing method includes depositing the multilayer reflective film on the substrate to form a multilayered-reflective-film-provided substrate, performing defect inspection on the multilayered-reflective-film-provided substrate, depositing the laminated film on the multilayer reflective film of the multilayered-reflective-film-provided substrate, forming a fiducial mark serving as a reference of a defect position in defect information on an upper portion of the laminated film to form a reflective mask blank formed with the fiducial mark, and performing defect inspection of the reflective mask blank by using the fiducial mark as a reference.

WO 2017/169973 A discloses a method for manufacturing a reflective mask blank including at least a multilayer reflective film and an absorber film. The multilayer reflective film that reflects EUV light is formed on a substrate, and the absorber film that absorbs EUV light is formed on the multilayer reflective film. Specifically, WO 2017/169973 A discloses that the manufacturing method includes depositing the multilayer reflective film on the substrate to form a multilayered-reflective-film-provided substrate, performing defect inspection on the multilayered-reflective-film-provided substrate, depositing the absorber film on the multilayer reflective film of the multilayered-reflective-film-provided substrate, forming a reflective mask blank formed with an alignment region formed in an outer peripheral edge region of a pattern forming region by removing the absorber film so that the multilayer reflective film of a region including an element serving as a reference of defect information on the multilayer reflective film is exposed in the alignment region, and performing defect management of the reflective mask blank by using the alignment region.

WO 2020/95959 A discloses a multilayered-reflective-film-provided substrate including a substrate and a multilayer reflective film that reflects EUV light formed on the substrate. Specifically, WO 2020/95959 A discloses that a multilayered-reflective-film-provided substrate includes a reference mark serving as a reference of a defect position in the multilayered-reflective-film-provided substrate and that the number of the reference marks is a number calculated in advance by a predetermined procedure. As the predetermined procedure, the following is described. That is, in the predetermined procedure (1), first defect coordinates of a defect in another multilayered-reflective-film-provided substrate having a plurality of reference marks and first reference mark coordinates of the reference marks are acquired by a defect inspection apparatus having a first coordinate system. In the predetermined procedure (2), second defect coordinates of the defect in the other multilayered-reflective-film-provided substrate and second reference mark coordinates of the reference marks are acquired by a coordinate measuring instrument having a second coordinate system. In the predetermined procedure (3), a conversion coefficient for converting coordinates from the first coordinate system to the second coordinate system is calculated based on the first reference mark coordinates and the second reference mark coordinates. In the predetermined procedure (4), the first defect coordinates acquired by the defect inspection apparatus in (1) is converted, using the conversion coefficient calculated in (3), into third defect coordinates based on the second coordinate system. In the predetermined procedure (5), the value of 3σ is calculated for the difference between the second defect coordinates acquired by the coordinate measuring instrument in the above (2) and the third defect coordinates converted in the above (4). In the predetermined procedure (6), a correspondence relation between the number of reference marks and 3σ is acquired. In the predetermined procedure (7), the number of reference marks at which the value of 3σ is less than 50 nm is determined.

In addition, WO 2014/104276 A and WO 2015/046303 A disclose a mask blank substrate used for lithography. WO 2014/104276 A and WO 2015/046303 A disclose that defect inspection is performed on a multilayered-reflective-film-provided substrate using a high-sensitivity defect inspection apparatus (“Teron 600 series” manufactured by KLA-Tencor Corporation) having an inspection light source wavelength of 193 nm and a high-sensitivity defect inspection apparatus (“MAGICS M7360” manufactured by Lasertec Corporation) having an inspection light source wavelength of 266 nm.

### SUMMARY

There has been proposed a technique for mitigating defects by correcting drawing data in such a manner as to form an absorber pattern at a position where there is a defect based on defect data about a mask blank and device pattern data (Defect Mitigation Technology, referred to as “DM technology” in this specification). In order to achieve the DM technology, in a reflective mask blank in which an absorber film is formed on a multilayer reflective film, when, for example, a pattern is drawn on a resist film formed on the absorber film by an electron beam lithography apparatus, a reference mark is detected with an electron beam by the electron beam lithography apparatus. In the DM technology, a pattern is drawn on a resist film based on pattern drawing data corrected and modified based on a reference point detected by an electron beam lithography apparatus.

In the meantime, a defect size required for an EUV mask, which is a reflective mask, is also becoming finer year by year as patterns are quickly refined in lithography using EUV light. In order to find such a fine defect, an inspection light source wavelength used in defect inspection is approaching a light source wavelength of exposure light (for example, EUV light).

As a defect inspection apparatus for an EUV mask, an EUV mask blank which is an original plate of an EUV mask, a multilayered-reflective-film-provided substrate, and a substrate, for example, a mask substrate/blank defect inspection apparatus “MAGICS M7360” for EUV exposure manufactured by Lasertec Corporation having an inspection light source wavelength of 266 nm, an EUV mask/blank defect inspection apparatus “Teron 600 series (for example, “Teron 610”)” manufactured by KLA-Tencor Corporation having an inspection light source wavelength of 193 nm, and the like are widely used. In recent years, an Actinic Blank Inspection (ABI) apparatus having an exposure light source wavelength of 13.5 nm as an inspection light source wavelength has been proposed.

However, it is difficult for a defect inspection apparatus having an inspection light source wavelength of 266 nm or 193 nm to find a fine defect. On the other hand, even when an ABI apparatus having an inspection light source wavelength of 13.5 nm performs highly accurate defect inspection on a reflective mask blank, it is difficult to detect all the defects and dimensions. Thus, a problem can occur in correction of drawing data by the DM technology.

For this reason, an aspect of the present disclosure is to provide a method for manufacturing a reflective mask capable of more accurately correcting drawing data based on defect inspection.

Another aspect of the present disclosure includes a method of manufacturing a multilayered-reflective-film-provided substrate for manufacturing a reflective mask capable of more accurately correcting drawing data based on defect inspection, and for manufacturing a reflective mask blank.

In order to solve the above problems, the present disclosure has the following configurations.

(Configuration 1)

Configuration 1 of the present disclosure is a method for manufacturing a multilayered-reflective-film-provided substrate including a substrate and a multilayer reflective film that reflects EUV light on the substrate, the method including:

performing a first defect inspection on the multilayered-reflective-film-provided substrate with a first wavelength to acquire first defect information;

performing a second defect inspection on the multilayered-reflective-film-provided substrate with a second wavelength different from the first wavelength to acquire second defect information; and

determining whether there is an unmatching defect and a matching defect by comparing the first defect information with the second defect information to acquire third defect information.

(Configuration 2)

Configuration 2 of the present disclosure is the method for manufacturing the multilayered-reflective-film-provided substrate according to Configuration 1, in which the second wavelength is a wavelength substantially equal to an exposure wavelength, and the first wavelength is a wavelength longer than the second wavelength.

(Configuration 3)

Configuration 3 of the present disclosure is the method for manufacturing the multilayered-reflective-film-provided substrate according to Configuration 1 or 2, in which

the multilayered-reflective-film-provided substrate includes a reference mark RM,

the first defect information includes first mark coordinates RM1 of the reference mark RM and first defect coordinates, and

the second defect information includes second mark coordinates RM2 of the reference mark RM and second defect coordinates, and

the acquiring the third defect information is based on converting, based on relative position coordinates of the first mark coordinates RM1 and the second mark coordinates RM2, the first defect coordinates using the first mark coordinates RM1 as a reference into a coordinate using the second mark coordinates RM2 as a reference.

(Configuration 4)

Configuration 4 of the present disclosure is the method for manufacturing the multilayered-reflective-film-provided substrate according to any one of Configurations 1 to 3, in which when there is the unmatching defect between the first defect information and the second defect information, the unmatching defect is used as a defect in a first defect map using the first mark coordinates RM1 as a reference, and

when there is the matching defect between the first defect information and the second defect information, the matching defect is used as a defect in a second defect map using the second mark coordinates RM2 as a reference.

(Configuration 5)

Configuration 5 of the present disclosure is the method for manufacturing the multilayered-reflective-film-provided substrate according to any one of Configurations 1 to 4, further including:

identifying a first unmatching defect detected only in the first defect inspection and a second unmatching defect detected only in the second defect inspection when there is the unmatching defect between the first defect information and the second defect information; and

performing a third defect inspection different from the first defect inspection and the second defect inspection on the multilayered-reflective-film-provided substrate, in which

the third defect inspection includes measuring a defect dimension of at least one of the matching defect and the first unmatching defect, and

the defect dimension measured in the third defect inspection is added to the third defect information.

(Configuration 6)

Configuration 6 of the present disclosure is the method for manufacturing the multilayered-reflective-film-provided substrate according to any one of Configurations 1 to 5, in which the multilayered-reflective-film-provided substrate further includes a protective film on the multilayer reflective film.

(Configuration 7)

Configuration 7 of the present disclosure is a reflective mask blank including:

a multilayered-reflective-film-provided substrate manufactured by the method for manufacturing the multilayered-reflective-film-provided substrate according to any one of Configurations 1 to 6; and

an absorber film formed on the multilayered-reflective-film-provided substrate.

(Configuration 8)

Configuration 8 of the present disclosure is the reflective mask blank according to Configuration 7, in which the absorber film includes a second reference mark FM formed on the absorber film and a transfer reference mark RM′ obtained by transferring the reference mark RM to the absorber film.

(Configuration 9)

Configuration 9 of the present disclosure is a method for manufacturing a reflective mask blank including:

identifying a first unmatching defect detected only in the first defect inspection and a second unmatching defect detected only in the second defect inspection when there is the unmatching defect between the first defect information and the second defect information about the reflective mask blank according to claim 7 or 8; and

performing a third defect inspection on the reflective mask blank with a third wavelength different from the first wavelength and the second wavelength, in which

the third defect inspection includes measuring a defect dimension of at least one of the matching defect transferred to the absorber film and the first unmatching defect, and

the defect dimension measured in the third defect inspection is added to the third defect information.

(Configuration 10)

Configuration 10 of the present disclosure is a method for manufacturing a reflective mask comprising: patterning the absorber film of the reflective mask blank according to Configuration 7 or 8 or a reflective mask blank manufactured by the method for manufacturing the reflective mask blank according to Configuration 9 to form an absorber pattern.

According to the present disclosure, it is possible to provide a method for manufacturing a reflective mask capable of more accurately correcting drawing data based on defect inspection.

According to the present disclosure, it is also possible to provide a method for manufacturing a multilayered-reflective-film-provided substrate for manufacturing a reflective mask capable of more accurately correcting drawing data based on defect inspection, and for manufacturing a reflective mask blank.

### BRIEF DESCRIPTION OF THE DRAWINGS

FIG. 1 is a schematic cross-sectional view of an example of a multilayered-reflective-film-provided substrate in the present embodiment;

FIG. 2 is a schematic cross-sectional view of another example of the multilayered-reflective-film-provided substrate in the present embodiment;

FIG. 3 is a schematic cross-sectional view of an example of a reflective mask blank in the present embodiment;

FIGS. 4A-4E are flow diagrams showing a method for manufacturing the reflective mask in the present embodiment in schematic cross-sectional views;

FIG. 5 is a schematic plan view of an example of the multilayered-reflective-film-provided substrate in the present embodiment;

FIG. 6 is a schematic plan view of another example of the multilayered-reflective-film-provided substrate in the present embodiment;

FIG. 7 is a schematic plan view of an example of the reflective mask blank in the present embodiment; and

FIG. 8 is a schematic plan view of an example of a shape of a reference mark (second reference mark FM).

### DETAILED DESCRIPTION

Hereinafter, an embodiment of the present disclosure will be specifically described with reference to the drawings. Note that the following embodiment is a form for concretely describing the present disclosure and does not limit the present disclosure within the scope thereof.

FIG. 1 is a schematic cross-sectional view of an example of a multilayered-reflective-film-provided substrate 110 in the present embodiment. The present embodiment is a method for manufacturing the multilayered-reflective-film-provided substrate 110 including a substrate 1 and a multilayer reflective film 5 that reflects EUV light on the substrate 1.

As shown in FIG. 1, the multilayered-reflective-film-provided substrate 110 in the present embodiment includes the multilayer reflective film 5 on the substrate 1. The multilayer reflective film 5 is a film for reflecting exposure light and is formed of a multilayer film in which low refractive index layers and high refractive index layers are alternately laminated. Note that the multilayered-reflective-film-provided substrate 110 in the present embodiment can include a back conductive film 2 on the back face of the substrate 1 (the main surface opposite to the main surface on which the multilayer reflective film 5 is formed).

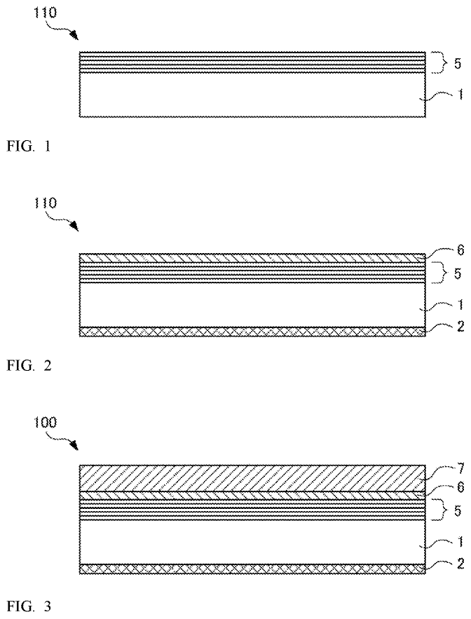

FIG. 2 is a schematic cross-sectional view of another example of the multilayered-reflective-film-provided substrate 110 in the present embodiment. In the example shown in FIG. 2, the multilayered-reflective-film-provided substrate 110 includes a protective film 6.

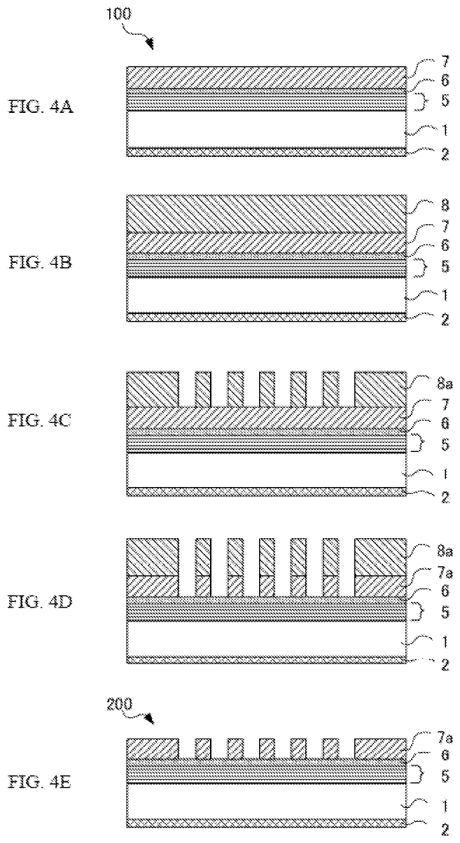

By using the multilayered-reflective-film-provided substrate 110 in the present embodiment, it is possible to manufacture a reflective mask blank 100. FIG. 3 is a schematic cross-sectional view of an example of the reflective mask blank 100 in the present embodiment. The reflective mask blank 100 further includes an absorber film 7.

Specifically, the reflective mask blank 100 in the present embodiment has the absorber film 7 on the outermost surface of the multilayered-reflective-film-provided substrate 110 (for example, the surface of the multilayer reflective film 5 or the protective film 6). By using the reflective mask blank 100 in the present embodiment, it is possible to obtain a reflective mask 200 capable of more accurately correcting drawing data based on defect inspection.

In the present specification, the “multilayered-reflective-film-provided substrate 110” is a predetermined substrate 1 on which the multilayer reflective film 5 is formed. FIGS. 1 and 2 show examples of schematic cross-sectional views of the multilayered-reflective-film-provided substrate 110. Note that the multilayered-reflective-film-provided substrate 110 includes a substrate on which a thin film other than the multilayer reflective film 5, for example, the protective film 6 and/or the back conductive film 2 is formed.

In the present specification, the “reflective mask blank 100” is the multilayered-reflective-film-provided substrate 110 on which the absorber film 7 is formed. The reflective mask blank 100 includes the multilayered-reflective-film-provided substrate 110 on which a thin film other than the absorber film 7 (for example, an etching mask film and/or a resist film 8 or the like) is further formed.

In the present specification, “disposing (forming) the absorber film 7 on the multilayer reflective film 5” includes disposing (forming) the absorber film 7 in contact with the surface of the multilayer reflective film 5 and having another film between the multilayer reflective film 5 and the absorber film 7. The same applies to other films. In addition, in the present specification, “disposing a film A in contact with the surface of a film B”, for example, is that the film A and the film B are disposed so as to be in direct contact with each other without interposing another film between the film A and the film B.

<Multilayered-Reflective-Film-Provided Substrate 110>

The substrate 1 and each thin film constituting the multilayered-reflective-film-provided substrate 110 in the present embodiment will be described.

<<Substrate 1>>

The substrate 1 in the multilayered-reflective-film-provided substrate 110 in the present embodiment is required to prevent occurrence of distortion of an absorber pattern 7a due to heat during EUV exposure. Thus, the substrate 1 having a low thermal expansion coefficient within a range of 0±5 ppb/° C. may be used. As a material having a low thermal expansion coefficient in this range, SiO₂—TiO₂ based glass, multicomponent glass ceramics, or the like can be used, for example.

A first main surface of the substrate 1 on which a transfer pattern (corresponding to the absorber pattern 7a described later) is to be formed is subjected to surface machining to have a predetermined flatness from the viewpoint of obtaining at least pattern transfer accuracy and positional accuracy. In the case of EUV exposure, the flatness may be 0.1 μm or less, may be 0.05 μm or less, and still may be 0.03 μm or less in a region of 132 mm×132 mm of the main surface on which the transfer pattern of the substrate 1 is to be formed. A second main surface (back surface) opposite to the side on which the absorber film 7 is to be formed is a surface to be electrostatically chucked when set in an exposure apparatus. The second main surface may have the flatness of 0.1 μm or less, may be 0.05 μm or less, and still may be 0.03 μm or less in a region of 142 mm×142 mm.

High surface smoothness of the substrate 1 is also an extremely important item. The surface roughness of the first main surface on which the transfer absorber pattern 7a is to be formed may be 0.15 nm or less in root mean square roughness (Rms), and may be 0.10 nm or less in Rms. The surface smoothness can be measured by an atomic force microscope.

In addition, the substrate 1 may have high stiffness in order to prevent deformation of a film (such as the multilayer reflective film 5) to be formed on the substrate 1 due to film stress. In particular, the substrate 1 may have a high Young's modulus of 65 GPa or more.

<<Multilayer Reflective Film 5>>

The multilayer reflective film 5 provides a function of reflecting EUV light in the reflective mask 200. The multilayer reflective film 5 has a multilayer structure in which layers having different refractive indices as the main components are periodically laminated.

In general, a multilayer film in which a thin film made of a light element which is a high refractive index material or a compound thereof (a high refractive index layer) and a thin film made of a heavy element which is a low refractive index material or a compound thereof (a low refractive index layer) are alternately laminated for about 40 to 60 periods is used as the multilayer reflective film 5. In the multilayer film, a laminated structure of a high refractive index layer/a low refractive index layer in which the high refractive index layer and the low refractive index layer are laminated in this order from the substrate 1 side as one period may be laminated for a plurality of periods. In addition, in the multilayer film, a laminated structure of a low refractive index layer/a high refractive index layer in which the low refractive index layer and the high refractive index layer are laminated in this order from the substrate 1 side as one period may be laminated for a plurality of periods. Note that the outermost layer of the multilayer reflective film 5, that is, the surface layer of the multilayer reflective film 5 on the side opposite to the substrate 1 may be a high refractive index layer. In the above multilayer film, if a laminated structure of a high refractive index layer/a low refractive index layer in which the high refractive index layer and the low refractive index layer are laminated in this order from the substrate 1 as one period is laminated for a plurality of periods, the uppermost layer is the low refractive index layer. In this case, if the low refractive index layer constitutes the outermost surface of the multilayer reflective film 5, the low refractive index layer is easily oxidized, and the reflectance of the reflective mask 200 lowers. Thus, it is possible to further form the high refractive index layer on the uppermost low refractive index layer to form the multilayer reflective film 5. On the other hand, in the above multilayer film, if a laminated structure of a low refractive index layer/a high refractive index layer in which the low refractive index layer and the high refractive index layer are laminated in this order from the substrate 1 side as one period is laminated for a plurality of periods, the uppermost layer is the high refractive index layer, and the above multilayer film can be directly used as the multilayer reflective film 5.

In the present embodiment, a layer containing silicon (Si) is adopted as the high refractive index layer. The material containing Si may be Si alone or a Si compound containing boron (B), carbon (C), nitrogen (N), and oxygen (O) in addition to Si. By using a layer containing Si as the high refractive index layer, it is possible to obtain the reflective mask 200 for EUV lithography having excellent reflectivity of EUV light. In the present embodiment, a glass substrate may be used as the substrate 1. Si is also excellent in adhesion to a glass substrate. As the low refractive index layer, an elemental metal selected from molybdenum (Mo), ruthenium (Ru), rhodium (Rh), and platinum (Pt), or an alloy thereof is used. As the multilayer reflective film 5 for EUV light having a wavelength of, for example, 13 nm to 14 nm, a Mo/Si periodic laminated film in which Mo films and Si films are alternately laminated for about 40 to 60 periods may be used. Note that a high refractive index layer, which is the uppermost layer of the multilayer reflective film 5, may be formed of silicon (Si), and a silicon oxide layer containing silicon and oxygen may be formed between the uppermost layer (Si) and the Ru-based protective film 6. This can improve the mask cleaning resistance.

The reflectance of this multilayer reflective film 5 alone is usually 65% or more, and the upper limit is usually 73%. The film thickness and period of each constituent layer of the multilayer reflective film 5 are only required to be appropriately selected according to the exposure wavelength and are selected in such a manner as to satisfy the Bragg's law. In the multilayer reflective film 5, there are a plurality of high refractive index layers and a plurality of low refractive index layers. The film thicknesses of the high refractive index layers and of the low refractive index layers may not be the same. In addition, the film thickness of the Si layer on the outermost surface of the multilayer reflective film 5 can be adjusted within a range in which the reflectance is not reduced. The film thickness of Si (high refractive index layer) on the outermost surface may be 3 nm to 10 nm.

A method for forming the multilayer reflective film 5 is known in the art. For example, the multilayer reflective film 5 can be formed by depositing each layer of the multilayer reflective film 5 by ion beam sputtering. In the case of the above Mo/Si periodic multilayer film, a Si film having a thickness of about 4 nm is first deposited on the substrate 1 using a Si target by, for example, ion beam sputtering. Thereafter, an Mo film having a thickness of about 3 nm is deposited using a Mo target. The multilayer reflective film 5 (the outermost layer is an Si layer) is formed by laminating for 40 to 60 periods in which the Si film and the Mo film are regarded as one period. In addition, to deposit the multilayer reflective film 5, it is possible to form the multilayer reflective film 5 by supplying krypton (Kr) ion particles from an ion source and performing ion beam sputtering. Note that the multilayer reflective film 5 may have about 40 periods in terms of improvement in reflectance due to an increase in the number of lamination periods, reduction in throughput due to an increase in the number of steps, and the like. However, the number of lamination periods of the multilayer reflective film 5 is not limited to 40 periods, and may be, for example, 60 periods. In the case of 60 periods, the number of steps is larger than 40 periods, but the reflectance to the EUV light can be increased.

<<Protective Film 6>>

As shown in FIG. 2, the multilayered-reflective-film-provided substrate 110 in the present embodiment may have the protective film 6 on the multilayer reflective film 5. Since the protective film 6 is formed on the multilayer reflective film 5, it is possible to reduce damage to the surface of the multilayer reflective film 5 when the reflective mask 200 is manufactured using the multilayered-reflective-film-provided substrate 110. Thus, the reflectance characteristic of the obtained reflective mask 200 with respect to the EUV light becomes favorable.

The protective film 6 is formed on the multilayer reflective film 5 in order to protect the multilayer reflective film 5 from dry etching and cleaning in manufacturing the reflective mask 200 described later. The protective film 6 also has a function of protecting the multilayer reflective film 5 at the time of black defect correction of a mask pattern using an electron beam (EB). Here, FIG. 2 shows that the protective film 6 has one layer. However, the protective film 6 may have a laminated structure of two layers. Alternatively, the protective film 6 may have a laminated structure of three or more layers, in which the lowermost layer and the uppermost layer are layers made of, for example, a substance containing Ru, and a metal other than Ru or an alloy can be interposed between the lowermost layer and the uppermost layer. The protective film 6 is formed of, for example, a material containing ruthenium as a main component. Examples of the material containing ruthenium as a main component include an Ru elemental metal, a Ru alloy containing at least one metal selected from titanium (Ti), niobium (Nb), rhodium (Rh), molybdenum (Mo), zirconium (Zr), yttrium (Y), boron (B), lanthanum (La), cobalt (Co), and rhenium (Re) in Ru, and materials containing nitrogen therein.

The Ru content ratio of the Ru alloy used for the protective film 6 is 50 at % or more and less than 100 at %, possibly 80 at % or more and less than 100 at %, and may be 95 at % or more and less than 100 at %. In particular, when the Ru content ratio of the Ru alloy is 95 at % or more and less than 100 at %, diffusion of the constituent elements (for example, silicon) of the multilayer reflective film 5 to the protective film 6 can be reduced. In addition, the protective film 6 in this case can have mask cleaning resistance, an etching stopper function when the absorber film 7 is etched, and a function of preventing temporal change in the multilayer reflective film 5, while sufficiently securing the reflectance of EUV light.

The film thickness of the protective film 6 is not particularly limited as long as it can function as the protective film 6. From the viewpoint of the reflectance of EUV light, the film thickness of the protective film 6 may be 1.0 nm to 8.0 nm, and may be 1.5 nm to 6.0 nm.

As a method for forming the protective film 6, a known film forming method can be adopted without particular limitation. Specific examples of the method for forming the protective film 6 include sputtering and ion beam sputtering.

<Method for Manufacturing Multilayered-Reflective-Film-Provided Substrate 110>

Next, a method for manufacturing the multilayered-reflective-film-provided substrate 110 in the present embodiment will be described.

In the method for manufacturing the multilayered-reflective-film-provided substrate 110 in the present embodiment, first, the substrate 1 is prepared, and the multilayer reflective film 5 is formed on the first main surface of the substrate 1 (see FIG. 1). The protective film 6 can be formed on the multilayer reflective film 5 as necessary (see FIG. 2). In the method for manufacturing the multilayered-reflective-film-provided substrate 110 in the present embodiment, the back conductive film 2 can be formed on the back face of the substrate 1 (the main surface opposite to the main surface on which the multilayer reflective film 5 is formed) (see FIG. 2).

<<Acquiring First Defect Information>>

The method for manufacturing the multilayered-reflective-film-provided substrate 110 in the present embodiment includes performing first defect inspection with a first wavelength on the main surface of the multilayered-reflective-film-provided substrate 110 on which the multilayer reflective film 5 is formed to acquire first defect information.

Note that the “defect information” in the present specification is information regarding a structure that can be evaluated as a defect detected in defect inspection and is, for example, data including position information, and the defect information also includes information regarding a structure that is not necessarily treated as a defect.

Note that the film thickness of the protective film 6 is 8 nm at the maximum as described above and is very thin. Thus, even when the protective film 6 is formed on the multilayer reflective film 5, defects in the multilayer reflective film 5 can be detected in defect inspection. The same applies to other defect inspections.

The “first wavelength” used in the first defect inspection is a wavelength different from a second wavelength for second defect inspection described later. The first wavelength can be a wavelength of, for example, 365 nm, 355 nm, 266 nm, 213 nm, 193 nm, or the like. When the first wavelength is 365 nm, as a defect inspection apparatus for the first defect inspection, a coordinate measuring instrument “LMS-IPRO4” manufactured by KLA-Tencor Corporation that performs coordinate measurement with a laser beam having a wavelength of 365 nm can be used, for example. When the first wavelength is 266 nm or 355 nm, as a defect inspection apparatus for the first defect inspection, a mask substrate/blank defect inspection apparatus “MAGICS M7360” or “MAGICS M8650” for EUV exposure manufactured by Lasertec Corporation having an inspection light source wavelength of 266 nm or 355 nm can be used, for example. When the first wavelength is 213 nm, a mask substrate/blank defect inspection apparatus “MAGICS M9650” for EUV exposure manufactured by Lasertec Corporation having an inspection wavelength of 213 nm can be used. When the first wavelength is 193 nm, an EUV mask/blank defect inspection apparatus “Teron 600 series, for example, Teron 610” manufactured by KLA-Tencor Corporation having an inspection light source wavelength of 193 nm or a coordinate measuring instrument “PROVE” manufactured by Carl Zeiss AG that performs coordinate measurement with a laser beam having a wavelength of 193 nm can be used. By performing defect inspection by a defect inspection apparatus or defect-coordinates measurement by a coordinate measuring instrument, it is possible to obtain information about the position and dimension of a defect on the multilayered-reflective-film-provided substrate 110 (first defect information).

Since the defect inspection can be accurately performed, a mask substrate/blank defect inspection apparatus “MAGICS M8650” having a first wavelength of 355 nm may be used for the first defect inspection.

The multilayered-reflective-film-provided substrate 110 may include a reference mark RM (for example, a dot mark). The reference mark RM can be referred to as an alignment mark (AM). An AM is a mark that can be used as a reference of defect coordinates when a defect on the multilayered-reflective-film-provided substrate 110 is inspected by a defect inspection apparatus. However, an AM is not directly used if a pattern is drawn by an electron beam lithography apparatus. The shape of the reference mark RM can be, for example, a dot mark, a substantially cross mark, or a square mark. The shape of the reference mark RM may be a dot mark or a substantially cross mark, and may be a circular dot mark because it is easily detected by a defect inspection apparatus. FIG. 5 shows an example in which a reference mark 20 that is a circular dot mark is formed as the reference mark RM. Since the multilayered-reflective-film-provided substrate 110 has the reference mark RM, the position coordinates of a defect obtained in defect inspection can be associated with the position coordinates of the reference mark RM. Thus, the position of a defect on the multilayered-reflective-film-provided substrate 110 can be identified more accurately.

The first defect information may include first mark coordinates RM1 of the reference mark RM and first defect coordinates.

In the present specification, the position coordinates of the reference mark RM measured in the first defect inspection can be referred to as “first mark coordinates RM1”. The first defect information can include the first mark coordinates RM1 of the reference mark RM. By identifying the position of a defect on the multilayered-reflective-film-provided substrate 110 in association with the position coordinates of the reference mark RM, it is possible to accurately identify the position of the defect measured in the first defect inspection.

FIG. 5 is a plan view of the multilayered-reflective-film-provided substrate 110 in the present embodiment. In the example shown in FIG. 5, two reference marks 20 as an example of the reference mark RM are formed in the vicinity of respective four corners of the substantially-rectangular multilayered-reflective-film-provided substrate 110. Each reference mark 20 is a mark used as a reference of a defect position in the defect information. FIG. 5 shows an example in which eight reference marks 20 are formed. The reference marks 20 are required to be arranged at least three corners of the four corners. Thus, the number of reference marks 20 is three or more, and may be four or more. In addition, one reference mark 20 may be arranged on each of the four corners, and two reference marks 20 are may be arranged on each of the four corners. In addition, three or more reference marks 20 are required to be arranged on at least two axes.

In the multilayered-reflective-film-provided substrate 110 shown in FIG. 5, in the case of the substrate 1 having a size of 152 mm×152 mm, the absorber pattern 7a is formed in a pattern formation region (region of 132 mm×132 mm) inside the broken line A when the reflective mask 200 is manufactured. The absorber pattern 7a is not formed in a region outside the broken line A when the reflective mask 200 is manufactured. The reference marks 20 may be formed in a region where the absorber pattern 7a is not formed, that is, a region on the broken line A or a region outside the broken line A.

As shown in FIG. 5, the reference marks 20 each have a circular dot shape. The diameter of each reference mark 20 having a circular dot shape is, for example, 200 nm or more and 10 μm or less. FIG. 5 shows an example of the reference marks 20 each having a circular dot shape, but the shape of the reference marks 20 is not limited thereto. The shape of the reference marks 20 may be, for example, a substantially cross shape, a substantially L shape in plan view, a triangle, a quadrangle, or the like.

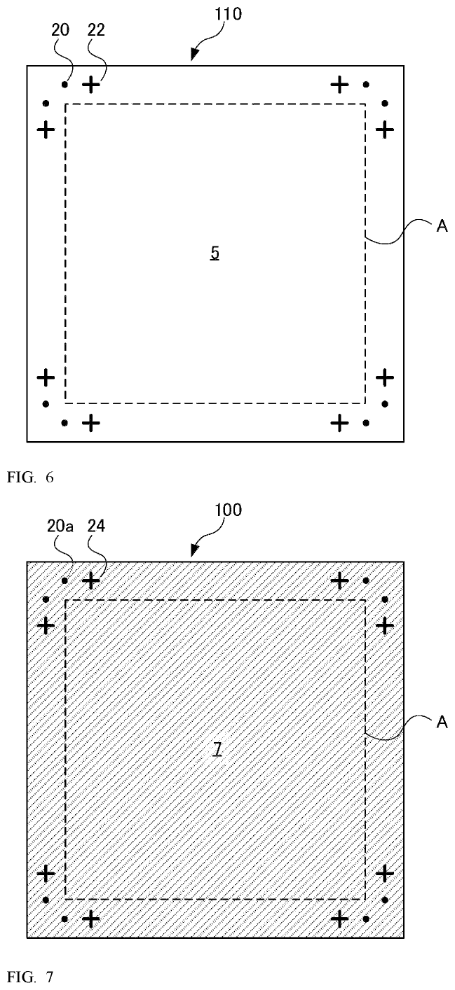

The multilayered-reflective-film-provided substrate 110 in the present embodiment can further include a reference mark CM having a shape or dimension different from that of the above reference mark RM. FIG. 6 shows the multilayered-reflective-film-provided substrate 110 having a reference mark 22 (reference mark CM) having a substantially cross shape in addition to the reference mark 20 (reference mark RM) having a circular dot shape. The reference mark CM may be the reference mark 22 having a substantially cross shape. When the multilayered-reflective-film-provided substrate 110 includes the reference mark CM, the first defect information and/or the second defect information can further include mark coordinates CM1 of the reference mark CM. When the absorber film 7 and the resist film 8 are formed on the multilayered-reflective-film-provided substrate 110, the dimensions (size and depth) of the reference mark CM can be adjusted in such a manner that the reference mark CM is transferred to the absorber film 7 and the resist film 8. Such a reference mark CM can be used as a second reference mark FM (a reference mark 24 shown in FIG. 7). The reference mark CM can be used as an alignment mark (AM). Since the multilayered-reflective-film-provided substrate 110 has the reference mark CM, a defect map (map indicating defect coordinates) based on the first and second defect inspections can be converted into a defect map using the second reference mark FM as a reference.

The cross-sectional shape of the reference mark 20 can be, for example, a recessed shape. The “recessed shape” is that the reference mark 20 is formed to be recessed downward, for example, in a stepped shape or a curved shape when the cross section of the multilayered-reflective-film-provided substrate 110 (the cross section perpendicular to the main surface of the multilayered-reflective-film-provided substrate 110) is viewed. The depth D of the reference mark 20 formed in the recessed shape may be 30 nm or more, and may be 40 nm or more. In addition, the depth D of the reference mark 20 may be a depth at which the substrate 1 is exposed. The depth D is a distance in the vertical direction from the surface of the multilayered-reflective-film-provided substrate 110 to the deepest position of the bottom of the reference mark 20.

A method for forming the reference mark 20 is not particularly limited. The reference mark 20 can be formed on the surface of the multilayered-reflective-film-provided substrate 110 by, for example, laser machining. At this time, the reference mark 20 is formed after the multilayer reflective film 5 is deposited, and then the protective film 6 can be deposited. In addition, the multilayer reflective film 5 and the protective film 6 are deposited first, and then the reference mark 20 can be formed. The laser machining conditions are, for example, as follows:

Type of laser (wavelength): ultraviolet to visible light region. For example, a semiconductor laser having a wavelength of 405 nm

Laser output: 1 to 120 mW

Scan speed: 0.1 to 20 mm/s

Pulse frequency: 1 to 100 MHz

Pulse width: 3 ns to 1000 s

The laser beam used for laser machining of the reference mark 20 may be a continuous wave or a pulse wave. In the case of using the pulse wave, the width W of the reference mark 20 can be further reduced compared to the case of using the continuous wave, even if the depth D of the reference mark 20 is substantially equal. Thus, in the case of using the pulse wave, it is possible to form the reference mark 20 having a larger contrast and easily detected by a defect inspection apparatus or an electron beam drawing apparatus, compared to the case of using the continuous wave.

A method for forming the reference mark 20 is not limited. The reference mark 20 can be formed by, for example, a method such as photolithography, a focused ion beam (FIB), a machining mark obtained by scanning a diamond needle, indentation by a micro indenter, and embossing such as imprinting.

The cross-sectional shape of the reference mark 20 is not limited to the recessed shape. For example, the cross-sectional shape of the reference mark 20 may be a protrusion shape protruding upward. When the cross-sectional shape of the reference mark 20 has a protrusion shape, the reference mark 20 can be formed by partial deposition such as FIB or sputtering. The height H of the reference mark 20 formed in the protrusion shape may be 30 nm or more, and may be 40 nm or more. The height H is a distance in the vertical direction from the surface of the multilayered-reflective-film-provided substrate 110 to the highest position of the reference mark 20.

When the reference mark 20 is formed on the multilayered-reflective-film-provided substrate 110, it is necessary to acquire the coordinates (mark coordinates RM1) of the reference mark 20 (reference mark RM) and the coordinates of a defect with high accuracy by a defect inspection apparatus. Thus, the reference mark 20 formed on the multilayered-reflective-film-provided substrate 110 needs to have a high enough contrast to be detectable by a defect inspection apparatus or a coordinate measuring instrument.

<<Acquiring Second Defect Information>>

The method for manufacturing the multilayered-reflective-film-provided substrate 110 in the present embodiment includes performing second defect inspection with a second wavelength different from the first wavelength on the main surface of the multilayered-reflective-film-provided substrate 110 on which the multilayer reflective film 5 is formed to acquire second defect information.

The “second wavelength” is used in the second defect inspection and is a wavelength different from the first wavelength for the first defect inspection described above. In the method for manufacturing the multilayered-reflective-film-provided substrate 110 in the present embodiment, the second wavelength may be substantially equal to an exposure wavelength. The “wavelength equal to the exposure wavelength” can be a wavelength of λ±1 nm as the exposure wavelength λ. For example, in the case of the exposure wavelength λ=13.5 nm, the second wavelength can be a wavelength of 12.5 to 14.5 nm. Specifically, an Actinic Blank Inspection (ABI) apparatus having an inspection light source wavelength that is the same as the exposure light source wavelength of 13.5 nm can be used as an apparatus for the second defect inspection. Since the second wavelength is substantially equal to the exposure wavelength, fine defects can be detected.

The first wavelength may be longer than the second wavelength. Specifically, a wavelength of about 193 to 365 nm can be used as the first wavelength for the first defect inspection, and a wavelength of 12.5 to 14.5 nm can be used as the second wavelength for the second defect inspection. Since the first wavelength is longer than the second wavelength, it can be possible to detect a defect different from a defect that can be detected with the second wavelength.

In the second defect inspection, the defect inspection is performed with the second wavelength to measure second defect coordinates. Since a wavelength different from that in the first defect inspection is used in the second defect inspection, the defect coordinates obtained in the second defect inspection (second defect coordinates) can be different from the first defect coordinates even if the defect is identical. In addition, a defect that cannot be detected in the first defect inspection can be detected in the second defect inspection. In addition, a defect that can be detected in the first defect inspection cannot be detected in the second defect inspection. In addition, the dimension of a defect that can be detected in the first defect inspection can be different from the defect detected in the second defect inspection. Thus, by performing the second defect inspection after the first defect inspection and comparing two pieces of information obtained from the two defect inspections, it is possible to obtain more accurate defect information.

The second defect information may include second mark coordinates RM2 of the reference mark RM and second defect coordinates.

In the present specification, the position coordinates of the reference mark RM (for example, the reference mark 20 shown in FIG. 5) measured in the second defect inspection can be referred to as “second mark coordinates RM2”. The reference mark RM is the same as that described in the first defect inspection. The second defect information can include the second mark coordinates RM2 of the reference mark RM. By identifying the position of a defect on the multilayered-reflective-film-provided substrate 110 in association with the position coordinates of the reference mark RM, it is possible to more accurately identify the position of the defect measured in the second defect inspection.

As another embodiment of the present embodiment, the first defect information and the second defect information can be different in information in the height direction.

That is the other embodiment is a method for manufacturing the multilayered-reflective-film-provided substrate 110 including the substrate 1 and the multilayer reflective film 5 that reflects EUV light on the substrate 1. The other embodiment includes performing a first defect inspection on the multilayered-reflective-film-provided substrate 110 with a first wavelength to acquire first defect information and performing a second defect inspection on the multilayered-reflective-film-provided substrate 110 with a second wavelength different from the first wavelength to acquire second defect information. In the other embodiment, the first defect information and the second defect information are different in information in the height direction. The height direction is a direction vertical to the main surface of the substrate 1. The information in the height direction is a position in the height direction where there is a defect and/or a size in the height direction of the dimensions of the defect. For example, the first defect information may include coordinates and/or a size in the height direction of a defect located near the surface layer of the multilayer reflective film 5, and the second defect information may include coordinates and/or a size in the height direction of a defect located inside the multilayer reflective film 5.

<<Step of Acquiring Third Defect Information>>

The method for manufacturing the multilayered-reflective-film-provided substrate 110 in the present embodiment includes determining whether there is an unmatching defect and a matching defect by comparing the first defect information with the second defect information to acquire third defect information.

Note that the “third defect information” in the present specification is data including defect information obtained based on the first defect information and the second defect information, and the third defect information also includes defect information obtained in a third defect inspection performed based on the first defect information and the second defect information.

Since the defect inspections are performed using different wavelengths in the first defect inspection and the second defect inspection, a defect that cannot be detected in the first defect inspection can be detected in the second defect inspection. In addition, a defect that can be detected in the first defect inspection cannot be detected in the second defect inspection. In addition, a defect similar to that detected in the first defect inspection can be detected in the second defect inspection. In addition, the defect coordinates obtained in the second defect inspection (the second defect coordinates) can have a different dimension from that obtained in the first defect coordinates even if the defect is the same. Thus, in order to acquire the third defect information, by comparing the first defect information with the second defect information, and it is determined whether there is an unmatching defect and a matching defect. For example, the coordinate system for the first defect inspection is affine-transformed into the coordinate system for the second defect inspection based on the first mark coordinates RM1 in the first defect inspection and the second mark coordinates RM2 in the second defect inspection. By comparing a value (defect distance) calculated in consideration of the distance between the affine-transformed first defect coordinates and the second defect coordinates, the coordinate accuracy of the first defect inspection, and the coordinate accuracy of the second defect inspection with a value (defect length, that is, distance) calculated based on the dimensions of the first defect and the second defect, it can be determined as a matching defect when the defect distance is shorter than the defect length. As a result, information such as the position coordinates of a defect can be identified more accurately.

In the present specification, an “unmatching defect” is a defect that can be detected in the first defect inspection but is not detected in the second defect inspection, or a defect that can be detected in the second defect inspection but is not detected in the first defect inspection.

In addition, in the present specification, a “matching defect” is a defect that can be detected in the first defect inspection and is also detected in the second defect inspection.

In the acquiring the third defect information, it is possible to acquire the third defect information by converting the first defect coordinates using the first mark coordinates RM1 as a reference into the coordinates using the second mark coordinates RM2 as a reference based on the relative position coordinates of the first mark coordinates RM1 and the second mark coordinates RM2. When the third defect information is acquired, the first defect coordinates in the coordinate system for the first defect inspection can be converted into the coordinate system for the second defect inspection.

In the method for manufacturing the multilayered-reflective-film-provided substrate 110 in the present embodiment, when there is an unmatching defect between the first defect information and the second defect information, the unmatching defect may be used as a defect in a first defect map using the first mark coordinates RM1 as a reference. The first defect map is a defect map indicating defect coordinates using the first mark coordinates RM1 (the position coordinates of the reference mark RM measured in the first defect inspection) as a reference.

In the second defect inspection using the second wavelength shorter than the first wavelength, a defect located near the surface of an antireflection film cannot be detected. In this case, as the defect information about an unmatching defect, the first defect information obtained in the first defect inspection with the first wavelength can be adopted as the third defect information.

In the method for manufacturing the multilayered-reflective-film-provided substrate 110 in the present embodiment, when there is a matching defect between the first defect information and the second defect information, the matching defect may be used as a defect in a second defect map using the second mark coordinates RM2 as a reference. The second defect map is a defect map indicating defect coordinates using the second mark coordinates RM2 (the position coordinates of the reference mark RM measured in the second defect inspection) as a reference.

In general, the second defect inspection using inspection light having a short wavelength has higher measurement accuracy. Thus, in the case of a defect detected in both the first defect inspection and the second defect inspection (matching defect), the second defect information obtained in the second defect inspection with higher accuracy is adopted as the third defect information.

For an unmatching defect that cannot be detected in the second defect inspection, the first defect information can be used as the third defect information. In addition, for an unmatching defect that can be detected in the second defect inspection, the second defect information can be used as the third defect information. For a matching defect, the second defect information can be used as the third defect information. This is because that the second defect inspection using inspection light having a short wavelength generally has higher measurement accuracy.

The third defect information includes information obtained by converting defect dimensions in the first defect information and/or the second defect information. That is, the method for manufacturing the multilayered-reflective-film-provided substrate includes performing a first defect inspection having first coordinate accuracy on the multilayered-reflective-film-provided substrate to acquire first defect information, and performing a second defect inspection having second coordinate accuracy different from the first coordinate accuracy on the multilayered-reflective-film-provided substrate to acquire second defect information, and third defect information is acquired by performing size conversion of at least one of a defect dimension in the first defect information and a defect dimension in the second defect information.

The method for manufacturing the multilayered-reflective-film-provided substrate includes performing a first defect inspection having first coordinate accuracy on the multilayered-reflective-film-provided substrate to acquire first defect information, and performing a second defect inspection having second coordinate accuracy different from the first coordinate accuracy on the multilayered-reflective-film-provided substrate to acquire second defect information, and a matching defect, a first unmatching defect detected only in the first defect inspection, and a second unmatching defect detected only in the second defect inspection are identified by comparing the first defect information with the second defect information, and third defect information is acquired by performing size conversion of a defect dimension of at least one of the matching defect, the first unmatching defect, and the second unmatching defect.

For the first defect inspection having the first coordinate accuracy, a defect inspection apparatus using the above first wavelength can be used. For the second defect inspection having the second coordinate accuracy, a defect inspection apparatus using the above second wavelength can be used.

The defect dimension includes a length (width), a height, or a depth in each of the X direction and the Y direction with respect to the multilayered-reflective-film-provided substrate 110.

The size conversion may be performed on both the defect dimension in the first defect information and the defect dimension in the second defect information, or may be performed only on either the defect dimension in the first defect information or the defect dimension in the second defect information. If the first coordinate accuracy is lower than the second coordinate accuracy, it is possible to perform size conversion on the defect dimension in the first defect information. When the second coordinate accuracy is higher than the first coordinate accuracy, the size conversion can be performed only on the defect dimension in the first defect information of the defect dimension in the first defect information and the defect dimension in the second defect information.

The size conversion may be performed on all of the matching defect dimension, the first unmatching defect dimension, and the second unmatching defect dimension, or may be performed on only one of the matching defect dimension, the first unmatching defect dimension, and the second unmatching defect dimension. If the first coordinate accuracy is lower than the second coordinate accuracy, it is possible to perform size conversion on the first unmatching defect dimension. If the second coordinate accuracy is higher than the first coordinate accuracy, the size conversion can be performed only on the defect dimension in the first defect information among the matching defect dimension, the first unmatching defect dimension, and the second unmatching defect dimension.

The size conversion is performed by adding a predetermined size (buffer value) to the acquired defect dimension. For example, a nm is added as a buffer value to the length in the X direction of the defect dimension in the first defect information or of the first unmatching defect, and a nm is added to the length in the Y direction. As a buffer value, 13 nm is added to the length in the X direction of the defect dimension in the second defect information or of the second unmatching defect, or the matching defect, and β nm is added to the length in the Y direction.

The value a is set according to the first coordinate accuracy, and the value β is set according to the second coordinate accuracy. When the first coordinate accuracy is lower than the second coordinate accuracy, it is possible to be α>β (β includes zero).

When buffer values added to the length in the X direction and the length in the Y direction of the defect dimension of the second unmatching defect and the matching defect, a buffer value for the second unmatching defect dimension and a buffer value for the matching defect dimension may be different values. For example, β1 nm is added as a buffer value to the length in the X direction and the length in the Y direction of the second unmatching defect dimension, and β2 nm is added as a buffer value to the length in the X direction and the length in the Y direction of the matching defect dimension. When the first coordinate accuracy is lower than the second coordinate accuracy, it is possible to be β2>β1 (β1 includes zero).

By manufacturing the multilayered-reflective-film-provided substrate 110 having the third defect information, it is possible to obtain the multilayered-reflective-film-provided substrate 110 for manufacturing the reflective mask 200 capable of more accurately correcting drawing data based on defect inspection.

<<Third Defect Inspection>>

The method for manufacturing the multilayered-reflective-film-provided substrate 110 in the present embodiment can include a third defect inspection. The third defect inspection can include the following steps.

The method for manufacturing the multilayered-reflective-film-provided substrate 110 in the present embodiment may further include, for the third defect inspection, identifying a first unmatching defect detected only in the first defect inspection and a second unmatching defect detected only in the second defect inspection when there is an unmatching defect between the first defect information and the second defect information.

The first unmatching defect is a defect that is detected only in the first defect inspection and is not detected in the second defect inspection. The second unmatching defect is a defect that is detected only in the second defect inspection and is not detected in the first defect inspection. By identifying the first unmatching defect and the second unmatching defect, it is possible to obtain guidelines for determining which of the first defect information and the second defect information should be adopted.

The method for manufacturing the multilayered-reflective-film-provided substrate 110 in the present embodiment may further include performing a third defect inspection on the multilayered-reflective-film-provided substrate 110 with a third wavelength different from the first wavelength and the second wavelength. The method may further include performing the third defect inspection on the multilayered-reflective-film-provided substrate 110 by an apparatus or a measurement method different from that used for the first defect inspection and the second defect inspection. The third defect inspection may include measuring a defect dimension of at least one of the matching defect and the first unmatching defect. In the third defect inspection, the defect coordinates can be measured together with the defect dimension. The defect dimension includes a length (width), a height, or a depth in each of the X direction and the Y direction with respect to the multilayered-reflective-film-provided substrate 110.

The defect dimension measured in the third defect inspection may be added to the third defect information. When the defect coordinates are measured in the third defect inspection, the defect coordinates can also be added to the third defect information.

As a defect inspection apparatus for the third defect inspection, a coordinate measuring instrument “LMS-IPRO4” manufactured by KLA-Tencor Corporation that performs coordinate measurement with a laser beam having a wavelength of 365 nm or a coordinate measuring instrument “PROVE” manufactured by Carl Zeiss AG that performs coordinate measurement with a laser beam having a wavelength of 193 nm can be used, for example. From the viewpoint of obtaining a clear observation image, it is possible to use “PROVE” as a defect inspection apparatus for the third defect inspection.

The third defect inspection may include a method for measuring the surface shape of a defect. For example, an atomic force microscope (AFM), a scanning electron microscope (SEM), or an EUV light microscope capable of obtaining irregularity information of the surface of a defect can be used. The third defect inspection may also include a partial inspection that measures a predetermined region (for example, a region of 1 μm×1 μm) including at least one of the matching defect and the first unmatching defect. In addition, the third defect inspection may include a partial inspection in which, when there are a predetermined region including at least one matching defect, a predetermined region including at least one first unmatching defect, and a predetermined region including at least one second unmatching defect and when the first coordinate accuracy is lower than the second coordinate accuracy, the predetermined region including at least one first unmatching defect and the predetermined region including at least one matching defect are measured without measuring the predetermined region including only the second unmatching defect. In addition, the third defect inspection may include a partial inspection in which, when there are a predetermined region including at least one matching defect, a predetermined region including at least one first unmatching defect, and a predetermined region including at least one second unmatching defect and when the first coordinate accuracy is lower than the second coordinate accuracy, the predetermined region including at least one first unmatching defect is measured without measuring the predetermined region including only the matching defect or the second unmatching defect.

By performing the third defect inspection, it is possible to obtain more accurate coordinates of the defect center. Thus, if the coordinates of the defect center in the first defect inspection and/or the second defect inspection is shifted from the coordinates of the defect center in the third defect inspection, the defect coordinates in the third defect inspection can be used. Accordingly, it is possible to obtain the multilayered-reflective-film-provided substrate 110 for manufacturing the reflective mask 200 capable of more accurately correcting drawing data based on defect inspection. In addition, by performing the third defect inspection as a partial inspection for measuring only a predetermined region, it is possible to shorten the time required for the third defect inspection and more efficiently obtain the multilayered-reflective-film-provided substrate 110 for manufacturing the reflective mask 200 capable of more accurately correcting drawing writing data based on the defect inspection. Performing the third defect inspection as the partial inspection based on the first defect information and the second defect information has a particularly excellent effect when the third defect inspection has high measurement accuracy but takes a long time to measure a predetermined region.

Since the method for manufacturing the multilayered-reflective-film-provided substrate 110 further includes the third defect inspection, it is possible to obtain the multilayered-reflective-film-provided substrate 110 for manufacturing the reflective mask 200 capable of more accurately correcting drawing data based on defect inspection.

<<Multilayered-Reflective-Film-Provided Substrate 110 Including Defect Information>>

The multilayered-reflective-film-provided substrate 110 can include the physical structures of the substrate 1 and the multilayer reflective film 5 as well as defect information (third defect information) regarding the position and dimension of a defect on the multilayer reflective film 5.

The multilayered-reflective-film-provided substrate 110 (and/or the reflective mask blank 100) is usually delivered to a customer together with defect information as data. Thus, it can be said that the defect information is a part of the multilayered-reflective-film-provided substrate 110. For example, the defect information is delivered to a customer together with a storage medium associated with the multilayered-reflective-film-provided substrate 110 (and/or the reflective mask blank 100) or associated with a substrate case storing the multilayered-reflective-film-provided substrate 110 (and/or the reflective mask blank 100), or delivered to a customer via a server connected to a network such as what is called Internet. The defect information can be information about the position and dimension of a defect on the multilayer reflective film 5. Thus, the method for manufacturing the multilayered-reflective-film-provided substrate 110 in the present embodiment can provide a customer with the third defect information obtained from the first defect information and the second defect information as the defect information about the multilayer reflective film 5. Since the multilayered-reflective-film-provided substrate 110 includes the defect information (third defect information), it is possible to manufacture the reflective mask 200 capable of more accurately correcting drawing data based on defect inspection.

<Reflective Mask Blank 100>

An embodiment of the reflective mask blank 100 in the present embodiment will be described.

As shown in FIG. 3, the reflective mask blank 100 in the present embodiment includes the multilayered-reflective-film-provided substrate 110 manufactured as described above and the absorber film 7 formed on the multilayered-reflective-film-provided substrate 110. By using the reflective mask blank 100 in the present embodiment, it is possible to manufacture the reflective mask 200 capable of more accurately correcting drawing data based on defect inspection.

<<Absorber Film 7>>

The reflective mask blank 100 has the absorber film 7 on the multilayered-reflective-film-provided substrate 110 described above. That is, the absorber film 7 is formed on the multilayer reflective film 5 (on the protective film 6 if the protective film 6 is formed). A basic function of the absorber film 7 is to absorb EUV light. The absorber film 7 may be the absorber film 7 for absorbing EUV light or may be the absorber film 7 having a phase shift function in consideration of the phase difference of EUV light. The absorber film 7 having a phase shift function absorbs EUV light and reflects a part of the EUV light to shift the phase. That is, in the reflective mask 200 in which the absorber film 7 having the phase shift function is patterned, a portion where the absorber film 7 is formed reflects a part of light at a level that does not adversely affect pattern transfer while absorbing and attenuating EUV light. In addition, a region (field portion) where the absorber film 7 is not formed reflects EUV light by the multilayer reflective film 5 via the protective film 6. Thus, a desired phase difference is provided between the reflected light from the absorber film 7 having the phase shift function and the reflected light from the field portion. The absorber film 7 having the phase shift function is formed in such a manner that the phase difference between the reflected light from the absorber film 7 and the reflected light from the multilayer reflective film 5 is 170 degrees to 190 degrees. The light beams having the inverted phase difference of about 180 degrees interfere with each other at the pattern edge portion, and this improves the image contrast of the projection optical image. As the image contrast is improved, the resolution is increased, and various tolerances regarding exposure such as exposure tolerance and focus tolerance can be increased.

The absorber film 7 can be a single-layer film. The absorber film 7 can be a multilayer film including a plurality of films. If the absorber film 7 is a single-layer film, it has characteristics that the number of steps at the time of manufacturing the mask blank can be reduced and that the production efficiency is increased. In the case of a multilayer film, its optical constant and film thickness can be appropriately set in such a manner that the upper absorber film serves as an antireflection film during mask pattern inspection using light. This improves inspection sensitivity during mask pattern inspection using light. In addition, if a film to which oxygen (O), nitrogen (N), or the like improving oxidation resistance is added is used as the upper absorber film, temporal stability is improved. In this manner, by forming the absorber film 7 as a multilayer film, various functions can be added. If the absorber film 7 is the absorber film 7 having the phase shift function, the range of adjustment in the optical surface can be increased by forming the absorber film 7 as a multilayer film, and a desired reflectance is easily obtained.

The material of the absorber film 7 is not particularly limited as long as it has a function of absorbing EUV light and can be machined by etching or the like (for example, by dry etching with chlorine (Cl) or fluorine (F)-based gas). As those having such a function, at least one metal selected from palladium (Pd), silver (Ag), platinum (Pt), gold (Au), iridium (Ir), tungsten (W), chromium (Cr), cobalt (Co), manganese (Mn), tin (Sn), tantalum (Ta), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), or a compound thereof may be used.

The absorber film 7 can be formed by magnetron sputtering such as DC sputtering or RF sputtering. For example, the absorber film 7 can be deposited by reactive sputtering using argon gas to which oxygen or nitrogen is added, using a target containing tantalum and boron.

The recessed-shape reference mark 20 (reference mark RM) formed on the multilayered-reflective-film-provided substrate 110 can be transferred to the absorber film 7 and the resist film 8. If an etching mask film is formed between the absorber film 7 and the resist film 8, the recessed-shape reference mark 20 formed on the multilayered-reflective-film-provided substrate 110 can be transferred to the absorber film 7, the etching mask film, and the resist film 8. The same applies to the case where the reference mark 22 (reference mark CM) is formed on the multilayered-reflective-film-provided substrate 110.

The absorber film 7 of the reflective mask blank 100 in the present embodiment may include a second reference mark FM formed on the absorber film 7 and a transfer reference mark RM′ obtained by transferring the reference mark RM to the absorber film 7.

The second reference mark FM can be formed on the absorber film 7 of the reflective mask blank 100 without being formed on the multilayered-reflective-film-provided substrate 110. FIG. 7 is a plan view of the reflective mask blank 100 formed with a substantially cross-shaped reference mark 24 that is the second reference mark FM. Note that the reflective mask blank 100 shown in FIG. 7 shows that the reference mark 20 (reference mark RM) formed on the multilayer reflective film 5 of the multilayered-reflective-film-provided substrate 110 as shown in FIG. 5 is transferred to the absorber film 7 as a reference mark 20a (transfer reference mark RM′).

The second reference mark FM can be formed on the multilayered-reflective-film-provided substrate 110 as the reference mark CM. That is, the multilayered-reflective-film-provided substrate 110 shown in FIG. 6 is formed with the reference mark 20 (reference mark RM) and the reference mark 22 (reference mark CM). If the absorber film 7 is formed on the multilayered-reflective-film-provided substrate 110 shown in FIG. 6, these reference marks 20 and 22 are transferred to the absorber film 7. As a result, in the reflective mask blank 100 shown in FIG. 7, these reference marks 20 and 22 are the reference mark 20a (transfer reference mark RM′) and the reference mark 24. The reference mark 24 can be used as the second reference mark FM.

The reference mark 24 (second reference mark FM) can be used as, for example, a fiducial mark (FM). An FM is a mark used as a reference of defect coordinates when a pattern is drawn by an electron beam lithography apparatus. The FM usually has a cross shape as shown by a reference sign 24 in FIG. 7.

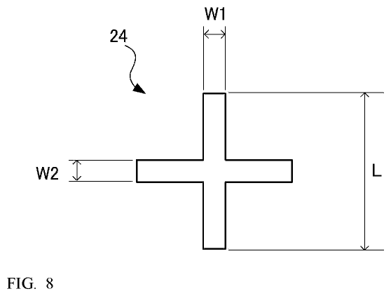

FIG. 8 is a schematic diagram of the shape of the reference mark 24 (second reference mark FM) that can be used as a fiducial mark (FM). The width W1 and width W2 of the reference mark 24 having a substantially cross shape are, for example, 200 nm or more and 10 μm or less. The length L of the reference mark 24 is, for example, 100 μm or more and 1500 μm or less. FIG. 8 shows an example of the reference mark 24 having a substantially cross shape, but the shape of the reference mark 24 is not limited thereto. The shape of the reference mark 24 may be, for example, a substantially L shape in plan view, a circle, a triangle, a quadrangle, or the like.

By using the reference mark 24 (second reference mark FM) as an FM, it is possible to manage the defect coordinates with high accuracy. When a pattern is drawn on the resist film 8 by an electron beam lithography apparatus, the reference mark 24 transferred to the resist film 8 is used as an FM that is a reference of a defect position. For example, by detecting the FM by a coordinate measuring instrument of the electron beam lithography apparatus, the defect coordinates acquired by the defect inspection apparatus can be converted into the coordinate system of the electron beam lithography apparatus. Accordingly, the drawing data for the pattern to be drawn by the electron beam lithography apparatus can be corrected in such a manner that, for example, the defect is arranged under the absorber pattern 7a (DM technology). By correcting the drawing data, it is possible to reduce the influence of the defect on the finally manufactured reflective mask 200.

The absorber film 7 may include the second reference mark FM formed on the absorber film 7, and the transfer reference mark RM′ obtained by transferring the reference mark RM to the absorber film 7 and/or a transfer reference mark CM′ obtained by transferring the reference mark CM to the absorber film 7.

The reference mark 22 (reference mark CM) shown in FIG. 6 can be used as an alignment mark (AM). If the reference mark RM is difficult to be transferred to the absorber film 7 or the transfer reference mark RM′ transferred to the absorber film 7 is difficult to be detected by an electron beam, the transfer reference mark CM′ obtained by transferring the reference mark CM to the absorber film 7 can be used.

If the reference mark 22 (reference mark CM) is used as an AM, the widths W1 and W2 of the reference mark 22 having, for example, a substantially cross shape are, for example, 200 nm or more and 10 μm or less. The length L of the reference mark 22 is, for example, 100 μm or more and 1500 μm or less. The shape of the reference mark 22 is not limited to the substantially cross shape, and may be, for example, a substantially L shape in plan view, a circle, a triangle, a quadrangle, or the like.

If an AM (the reference mark 20, or the reference mark 20 and the reference mark 22) is formed on the multilayered-reflective-film-provided substrate 110, an FM (the second reference mark FM that is the reference mark 24) is formed on the absorber film 7 on the multilayered-reflective-film-provided substrate 110. The AM is transferred to the absorber film 7. The AM can be detected by a defect inspection apparatus and a coordinate measuring instrument. The FM can be detected by a coordinate measuring instrument and an electron beam lithography apparatus. Since both the AM and the FM can be detected by a coordinate measuring instrument, the relative position relation therebetween can be managed with high accuracy. Thus, the defect coordinates using the AM as a reference acquired by a defect inspection apparatus can be converted into the defect coordinates using the FM as a reference used in an electron beam lithography apparatus with high accuracy. Note that the number of AMs can be larger than the number of FMs. In addition, by partially removing the absorber film 7 on an AM, the detection accuracy of the AM can be improved.

In the method for manufacturing the reflective mask blank 100 in the present embodiment, it is possible to perform defect inspection on the reflective mask blank 100 by the procedure similar to the third defect inspection performed on the multilayered-reflective-film-provided substrate 110 described above.

The method for manufacturing the reflective mask blank 100 in the present embodiment may further include, before performing the third defect inspection, identifying a first unmatching defect detected only in the first defect inspection and a second unmatching defect detected only in the second defect inspection when there is an unmatching defect between the first defect information and the second defect information about the multilayered-reflective-film-provided substrate 110.

The first unmatching defect is a defect that is detected only in the first defect inspection in the method for manufacturing the multilayered-reflective-film-provided substrate 110 and is not detected in the second defect inspection. The second unmatching defect is a defect that is detected only in the second defect inspection in the method for manufacturing the multilayered-reflective-film-provided substrate 110 and is not detected in the first defect inspection. By identifying the first unmatching defect and the second unmatching defect, it is possible to obtain guidelines for determining which of the first defect information and the second defect information should be adopted.

The method for manufacturing the reflective mask blank 100 in the present embodiment may further include performing a third defect inspection on the reflective mask blank 100 with a third wavelength different from the first wavelength and the second wavelength. The method may further include performing the third defect inspection on the reflective mask blank 100 by an apparatus or a measurement method different from that used for the first defect inspection and the second defect inspection. The third defect inspection may include measuring a defect dimension of at least one of the matching defect transferred to the absorber film 7 and the first unmatching defect. In the third defect inspection, the defect coordinates can be measured together with the defect dimension. The defect dimension includes a length (width), a height, or a depth in each of the X direction and the Y direction with respect to the multilayered-reflective-film-provided substrate 110.

In addition, the defect dimension measured in the third defect inspection may be added to the third defect information. When the defect coordinates are measured in the third defect inspection, the defect coordinates can also be added to the third defect information.

As a defect inspection apparatus for the third defect inspection to be performed on the reflective mask blank 100, a coordinate measuring instrument “LMS-IPRO4” manufactured by KLA-Tencor Corporation that performs coordinate measurement with a laser beam having a wavelength of 365 nm or a coordinate measuring instrument “PROVE” manufactured by Carl Zeiss AG that performs coordinate measurement with a laser beam having a wavelength of 193 nm can be used, for example. From the viewpoint of obtaining a clear observation image, it is possible to use “PROVE” as a defect inspection apparatus for the third defect inspection.

The third defect inspection may include a method for measuring the surface shape of a defect. For example, an atomic force microscope (AFM), a scanning electron microscope (SEM), or an EUV light microscope capable of obtaining irregularity information of the surface of a defect can be used. The third defect inspection may also include a partial inspection that measures a predetermined region (for example, a region of 1 μm×1 μm) including at least one of the matching defect and the first unmatching defect.

Since the method for manufacturing the reflective mask blank 100 further includes the third defect inspection, it is possible to obtain the reflective mask blank 100 for manufacturing the reflective mask 200 capable of more accurately correcting drawing data based on defect inspection.

<<Back Conductive Film 2>>

The back conductive film 2 for an electrostatic chuck is formed on a second main surface (back surface) of the substrate 1 (on the opposite side of the surface on which the multilayer reflective film 5 is formed, and on an intermediate layer if the intermediate layer such as a hydrogen entry preventing film is formed on the substrate 1). The sheet resistance required for the back conductive film 2 for an electrostatic chuck is usually 100Ω/□ or less. The method for forming the back conductive film 2 is, for example, magnetron sputtering or ion beam sputtering using a target of a metal such as chromium or tantalum or an alloy thereof. If the material of the back conductive film 2 contains chromium (Cr), the material may be a Cr compound containing at least one selected from boron, nitrogen, oxygen, and carbon in Cr. Examples of the Cr compound include CrN, CrON, CrCN, CrCON, CrBN, CrBON, CrBCN, CrBOCN, and the like. As the material containing tantalum (Ta) of the back conductive film 2, it is possible to use tantalum (Ta), an alloy containing Ta, or a Ta compound containing at least one of boron, nitrogen, oxygen, and carbon in any of these. Examples of the Ta compound include TaB, TaN, TaO, TaON, TaCON, TaBN, TaBO, TaBON, TaBCON, TaHf, TaHfO, TaHfN, TaHfON, TaHfCON, TaSi, TaSiO, TaSiN, TaSiON, TaSiCON, and the like. The film thickness of the back conductive film 2 is not particularly limited as long as the function for an electrostatic chuck is satisfied, but is usually 10 nm to 200 nm. The back conductive film 2 also serves for stress adjustment on the second main surface side of the reflective mask blank 100. That is, the back conductive film 2 is adjusted in such a manner as to obtain the flat reflective mask blank 100 in balance with stress from various films formed on the first main surface side.

Before the absorber film 7 is formed, the back conductive film 2 can be formed on the multilayered-reflective-film-provided substrate 110. In that case, the multilayered-reflective-film-provided substrate 110 including the back conductive film 2 as shown in FIG. 2 can be obtained.

<<Etching Mask Film>>

The reflective mask blank 100 manufactured by the manufacturing method in the present embodiment may include an etching mask film (also referred to as an “etching hard mask film”) on the absorber film 7. Examples of the typical material of the etching mask film include silicon (Si), a material obtained by adding at least one element selected from oxygen (O), nitrogen (N), carbon (C), and hydrogen (H) to silicon, chromium (Cr), or a material obtained by adding at least one element selected from oxygen (O), nitrogen (N), carbon (C), and hydrogen (H) to chromium. Specific examples include SiO₂, SiON, SiN, SiO, Si, SiC, SiCO, SiCN, SiCON, Cr, CrN, CrO, CrON, CrC, CrCO, CrCN, CrOCN, and the like. However, if the material of the absorber film 7 is a compound containing oxygen, it is possible to avoid to use a material containing oxygen (for example, SiO₂) for the etching mask film from the viewpoint of etching resistance. If the reflective mask blank 100 includes an etching mask film, the film thickness of the resist film 8 can be reduced at the time of manufacturing the reflective mask 200, which is advantageous for miniaturization of the pattern.

<<Other Thin Films>>

The reflective mask blank 100 manufactured by the manufacturing method in the present embodiment may include the resist film 8 on the absorber film 7 or the etching mask film. That is, the reflective mask blank 100 including the resist film 8 is included in the reflective mask blank 100 in the present embodiment.

<Reflective Mask 200>

The method for manufacturing the reflective mask 200 in the present embodiment includes patterning the absorber film 7 of the reflective mask blank 100 to form the absorber pattern 7a on the multilayer reflective film 5. That is, the reflective mask 200 in the present embodiment has the absorber pattern 7a on the multilayer reflective film 5. By using the reflective mask blank 100 in the present embodiment, it is possible to obtain a reflective mask 200 capable of more accurately correcting drawing data based on defect inspection.

The reflective mask 200 can be manufactured using the reflective mask blank 100 in the present embodiment. Here, only an outline is described, and the details will be described later with reference to the drawings.

By preparing the reflective mask blank 100, forming the resist film 8 on the outermost surface (on the absorber film 7 as described in the following example) of the first main surface (this is not necessary when the resist film 8 is provided as the reflective mask blank 100), drawing (exposing) a desired pattern such as a circuit pattern on the resist film 8, and further developing and rinsing the pattern, a predetermined resist pattern 8a is formed.

By dry-etching the absorber film 7 using the resist pattern 8a as a mask, the absorber pattern 7a is formed. As the etching gas, a gas selected from a chlorine-based gas such as Cl₂, SiCl₄, and CHCl₃, a mixed gas containing a chlorine-based gas and O₂ at a predetermined ratio, a mixed gas containing a chlorine-based gas and He at a predetermined ratio, a mixed gas containing a chlorine-based gas and Ar at a predetermined ratio, a fluorine-based gas such as CF₄, CHF₃, C₂F₆, C₃F₆, C₄F₆, C₄F₈, CH₂F₂, CH₃F, C₃F₈, SF₆, and F₂, a mixed gas containing a fluorine-based gas and O₂ at a predetermined ratio, and the like can be used. Here, if oxygen is contained in the etching gas at the final stage of etching, surface roughness occurs in the Ru-based protective film 6. Thus, at the over-etching stage in which the Ru-based protective film 6 is exposed to etching, it is possible to use an etching gas not containing oxygen.

Thereafter, the resist pattern 8a is removed by ashing or a resist stripping solution to manufacture the absorber pattern 7a on which the desired circuit pattern is formed.

Through the above, the reflective mask 200 in the present embodiment can be obtained.

By the method for manufacturing the reflective mask 200 in the present embodiment, it is possible to manufacture the reflective mask 200 capable of more accurately correcting drawing data based on defect inspection. That is, according to the present embodiment, the technique for reducing defects (DM technology) can be more appropriately applied at the time of manufacturing the reflective mask 200.

<Method for Manufacturing Semiconductor Device>

The method for manufacturing a semiconductor device in the present embodiment includes performing a lithography process by an exposure apparatus using the above reflective mask 200 to form a transfer pattern on a transfer object.

In the present disclosure, it is possible to more accurately correct drawing data based on defect inspection at the time of manufacturing the reflective mask 200. That is, according to the present embodiment, the technique for reducing defects (DM technology) can be more appropriately applied at the time of manufacturing the reflective mask 200. As a result, the throughput at the time of manufacturing the semiconductor device can be improved. In addition, since the semiconductor device can be manufactured using the reflective mask 200 having no defect that affects the transfer on the multilayer reflective film 5, it is possible to prevent a decrease in yield of the semiconductor device due to a defect on the multilayer reflective film 5.

By performing EUV exposure using the reflective mask 200 in the present embodiment, it is possible to form a desired transfer pattern on a semiconductor substrate. In addition to this lithography, by performing various steps such as etching of a film to be machined, forming an insulating film and a conductive film, introduction of a dopant, and annealing, it is possible to manufacture a semiconductor device on which a desired electronic circuit is formed at a high yield.

### EXAMPLES

Hereinafter, an embodiment of the present disclosure will be specifically described with reference to the drawings. Note that the following embodiment is a form for embodying the present disclosure and does not limit the present disclosure within the scope thereof.

### Example 1

As shown in FIG. 1, the multilayered-reflective-film-provided substrate 110 in Example 1 includes the substrate 1 and the multilayer reflective film 5.

As the substrate 1, an SiO₂—TiO₂-based glass substrate that was a low thermal expansion glass substrate having a 6025 size (about 152 mm×152 mm×6.35 mm) with both surfaces of the first main surface and the second main surface polished was used. In order to obtain flat and smooth main surfaces, polishing including a rough polishing, a precision polishing, a local machining, and a touch polishing were performed.

By periodically laminating a Mo film/Si film on the main surface of the substrate 1 opposite to the side on which the back conductive film 2 was to be formed, a multilayer reflective film 5 was formed.

Specifically, Mo films and Si films were alternately laminated on the substrate 1 by ion beam sputtering (using Ar) using a Mo target and a Si target. The thickness of the Mo film was 2.8 nm. The thickness of the Si film was 4.2 nm. The thickness of the Mo/Si film for one period was 7.0 nm. Such a Mo/Si film was laminated for 40 periods, and finally, a Si film was deposited with a film thickness of 4.0 nm to form the multilayer reflective film 5.

On the multilayer reflective film 5, the protective film 6 containing a Ru compound was formed. Specifically, a RuNb target (Ru: 80 at %, Nb: 20 at %) was used to form the protective film 6 made of a RuNb film on the multilayer reflective film 5 by DC magnetron sputtering in an Ar gas atmosphere. The thickness of the protective film 6 was 2.5 nm.

Next, the reference mark RM (reference mark 20) was formed on the protective film 6 by laser machining reaching the multilayer reflective film 5. The laser machining conditions were as follows:

Laser type: semiconductor laser having a wavelength of 405 nm

Output of laser: 7 mW (continuous wave)

Spot size: 430 nmφ

The shape and dimension of the reference mark 20 were as follows:

Shape: circle (dot mark)

Depth D: 40 nm

Diameter: 1.5 μm

As shown in FIG. 5, eight reference marks RM (reference marks 20) were formed. The reference marks 20 were formed outside the effective area of 132 mm×132 mm (area inside the broken line A) as shown in FIG. 5.

Next, the first defect inspection was performed on a defect on the multilayered-reflective-film-provided substrate 110 using a mask substrate/blank defect inspection apparatus “MAGICS M8650” for EUV exposure manufactured by Lasertec Corporation having an inspection light source wavelength of 355 nm, and the first defect coordinates and the dimension corresponding to the defect were acquired as first defect information. The first defect coordinates were measured using the reference marks RM as a reference. Thus, the first defect coordinates included the first mark coordinates RM1 of the reference marks RM. In this manner, a first defect map was able to be obtained as the first defect information. Table 1 shows the number of defects in the first defect inspection in Example 1.

Next, the second defect inspection was performed on a defect on the multilayered-reflective-film-provided substrate 110 using an Actinic Blank Inspection (ABI) apparatus having an inspection light source wavelength that is the same as the exposure light source wavelength of 13.5 nm, and the second defect coordinates and the dimension corresponding to the defect were acquired as second defect information. The second defect coordinates were measured using the reference marks RM as a reference. Thus, the second defect coordinates included the second mark coordinates RM2 of the reference marks RM. In this manner, a second defect map was able to be obtained as the second defect information. Table 1 shows the number of defects in the second defect inspection in Example 1.

Next, the first defect coordinates using the first mark coordinates RM1 as a reference was converted into the coordinates using the second mark coordinates RM2 as a reference based on the relative position coordinates of the first mark coordinates RM1 and the second mark coordinates RM2.

Next, the coordinates converted from the first defect information was compared with the second defect information to determine whether there were an unmatching defect and a matching defect. Table 1 shows the number of unmatching defects and the number of matching defects. For the unmatching defects, the number of unmatching defects detected only in the first defect inspection (first inspection) and the number of unmatching defects detected only in the second defect inspection (second inspection) were shown.

Next, when there was a matching defect between the first defect information and the second defect information, for the matching defect, a defect in the second defect map using the second mark coordinates RM2 as a reference was adopted as third defect information. In addition, for an unmatching defects that was not detected in the second defect inspection, the coordinates converted from the first defect information (a defect in the first defect map) were used as the third defect information. In addition, for an unmatching defects that was detected in the second defect inspection, the second defect information (a defect in the second defect map) was used as the third defect information.

In this manner, the multilayered-reflective-film-provided substrate 110 in Example 1 having the third defect information based on the first defect information and the second defect information was manufactured.

Next, the absorber film 7 was formed on the protective film 6 of the multilayered-reflective-film-provided substrate 110 in Example 1 to manufacture the reflective mask blank 100. Specifically, the absorber film 7 made of a laminated film of TaBN (thickness of 56 nm) and TaBO (thickness of 14 nm) was formed by DC magnetron sputtering. The TaBN film was formed by reactive sputtering in a mixed gas atmosphere of Ar gas and N₂ gas using a TaB target. The TaBO film was formed by reactive sputtering in a mixed gas atmosphere of Ar gas and O₂ gas using a TaB target. In this manner, the reflective mask blank 100 in Example 1 was manufactured.

Next, the second reference mark FM was formed on the surface of the reflective mask blank 100 in Example 1. FIG. 7 shows that the reference mark 24 was formed as the second reference mark FM. In the example of FIG. 7, eight second reference marks FM (reference marks 24) were formed. The reference marks 24 were formed outside the effective area of 132 mm×132 mm (area inside the broken line A) as shown in FIG. 7.

The second reference marks FM (reference marks 24) were formed on the absorber film 7 by laser machining. The laser machining conditions were as follows:

Laser type: semiconductor laser having a wavelength of 405 nm

Output of laser: 20 mW (continuous wave)

Spot size: 430 nmφ

The shape and dimension (see FIG. 8) of the second reference marks FM (reference marks 24) were as follows:

Shape: substantially cross shape

Depth D: 70 nm

Width W1 and width W2: 5 μm

Length L: 1 mm

Thereafter, the eight transfer reference marks RM′ transferred to the absorber film 7 and the eight second reference marks FM (reference marks 24) were measured using a coordinate measuring instrument “LMS-IPRO4” manufactured by KLA-Tencor Corporation that performed coordinate measurement with a laser beam having a wavelength of 365 nm. Based on the relative position coordinates of the transfer reference marks RM′ and the second reference marks FM, the above third defect information was converted into coordinates using the second reference marks FM as a reference to obtain a defect map having defect coordinates.

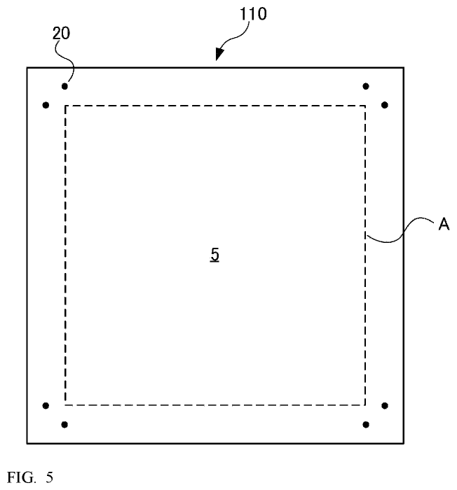

The reflective mask blank 100 in Example 1 manufactured as described above was used to manufacture the reflective mask 200. FIGS. 4A-4E are flow diagrams showing the method for manufacturing the reflective mask in schematic cross-sectional views.

First, on the absorber film 7 of the reflective mask blank 100 (see FIG. 4A) in Example 1, the resist film 8 was formed (see FIG. 4B).

Next, a pattern was drawn on the resist film 8 using an electron beam lithography apparatus. When a pattern was drawn, the defect map using the second reference marks FM (reference marks 24) as a reference of defect coordinates was used in order for the defect not to be located in the exposed region of the multilayer reflective film 5 of the absorber pattern 7a (DM technology). After the pattern was drawn, a predetermined development process was performed to form the resist pattern 8a on the absorber film 7 (see FIG. 4C).

The absorber pattern 7a was formed on the absorber film 7 using the resist pattern 8a as a mask (see FIG. 4D). Specifically, the upper TaBO film was dry-etched with a fluorine-based gas (CF₄ gas), and then the lower TaBN film was dry-etched with a chlorine-based gas (Cl₂ gas).

The resist pattern 8a remaining on the absorber pattern 7a was removed with hot sulfuric acid to obtain the reflective mask 200 in Example 1 (see FIG. 4E).

The EUV reflective mask 200 in Example 1 was inspected by a mask defect inspection apparatus (Teron 600 series manufactured by KLA-Tencor Corporation). As shown in Table 1, no defect was confirmed in the exposed region of the multilayer reflective film 5 of the absorber pattern 7a in this defect inspection.

### Example 2

In the multilayered-reflective-film-provided substrate 110 in Example 2, the multilayered-reflective-film-provided substrate 110 and the reflective mask blank 100 were manufactured in the same manner as in Example 1 except that a third defect inspection was performed with a third wavelength different from the first wavelength and the second wavelength.

That is, to manufacture the multilayered-reflective-film-provided substrate 110 in Example 2, the multilayered-reflective-film-provided substrate 110 having third defect information based on the first defect information and the second defect information was manufactured in the same manner as in Example 1. Next, by performing the third defect inspection on this multilayered-reflective-film-provided substrate 110, the multilayered-reflective-film-provided substrate 110 in Example 2 was manufactured. Table 1 shows the number of defects in the first to third defect inspections in Example 2.

For the third defect inspection on the multilayered-reflective-film-provided substrate 110 in Example 2, a coordinate measuring instrument “PROVE” manufactured by Carl Zeiss AG that performed coordinate measurement with a laser beam having a wavelength of 193 nm was used. In the third defect inspection, the defect coordinates and defect dimensions of a matching defect and a first unmatching defect (defect detected only in the first defect inspection and not detected in the second defect inspection) were measured. In the third defect inspection, a reference mark RM (reference mark 20) was used as a reference mark serving as a reference of coordinates.

Based on the defect information obtained in the third defect inspection, the defect dimension of the matching defect in the third defect information was changed to the defect dimension obtained in the third defect inspection. In the third defect information, the defect dimension and the coordinates of the first unmatching defect were changed to the defect dimension and the coordinates obtained in the third defect inspection. This was because the measurement values obtained in the third defect inspection were more reliable than the measurement values obtained in the first and second defect inspections.

In this manner, the multilayered-reflective-film-provided substrate 110 in Example 2 having the third defect information based on the first defect information, the second defect information, and the measurement values obtained in the third defect inspection was manufactured.

Next, the reflective mask blank 100 in Example 2 was manufactured in the same manner as in Example 1. The reflective mask blank 100 in Example 2 was used to manufacture the reflective mask 200 in Example 2 in the same manner as in Example 1.

The EUV reflective mask 200 in Example 2 was inspected by a mask defect inspection apparatus (Teron 600 series manufactured by KLA-Tencor Corporation). As shown in Table 1, no defect was confirmed in the exposed region of the multilayer reflective film 5 of the absorber pattern 7a in this defect inspection.

### Example 3

The multilayered-reflective-film-provided substrate 110 in Example 3 was manufactured in the same manner as in Example 1. Next, the reflective mask blank 100 in Example 3 was manufactured in the same manner as in Example 1 except that a third defect inspection was performed with a third wavelength different from the first wavelength and the second wavelength when the reflective mask blank 100 was manufactured.

That is, to manufacture the multilayered-reflective-film-provided substrate 110 in Example 3, first, the multilayered-reflective-film-provided substrate 110 having the third defect information based on the first defect information and the second defect information was manufactured in the same manner as in Example 1. Table 1 shows the number of defects in the first and second defect inspections in Example 3.

Next, to manufacture the reflective mask blank 100 in Example 3, the reflective mask blank 100 having the absorber film 7 was manufactured in the same manner as in Example 1. Next, the third defect inspection was performed on the reflective mask blank 100 in Example 3. Table 1 shows the number of defects in the third defect inspection in Example 3.

For the third defect inspection performed on the reflective mask blank 100 in Example 3, a coordinate measuring instrument “PROVE” manufactured by Carl Zeiss AG that performed coordinate measurement with a laser beam having a wavelength of 193 nm was used. In the third defect inspection, the defect coordinates and defect dimensions of a matching defect and a first unmatching defect (defect detected only in the first defect inspection and not detected in the second defect inspection) were measured. In the third defect inspection, a reference mark RM′ (reference mark 20a) was used as a reference mark serving as a reference of coordinates.

Based on the defect information obtained in the third defect inspection, the defect dimension of the matching defect in the third defect information was changed to the defect dimension obtained in the third defect inspection. In the third defect information, the defect dimension and the coordinates of the first unmatching defect were changed to the defect dimension and the coordinates obtained in the third defect inspection. This was because the measurement values obtained in the third defect inspection were more reliable than the measurement values obtained in the first and second defect inspections.

In this manner, the reflective mask blank 100 in Example 3 having the third defect information based on the first defect information, the second defect information, and the measurement values obtained in the third defect inspection was manufactured.

Next, the reflective mask blank 100 in Example 3 was used to manufacture the reflective mask 200 in Example 3 in the same manner as in Example 1.

The EUV reflective mask 200 in Example 3 was inspected by a mask defect inspection apparatus (Teron 600 series manufactured by KLA-Tencor Corporation). As shown in Table 1, no defect was confirmed in the exposed region of the multilayer reflective film 5 of the absorber pattern 7a in this defect inspection.

### Example 4

In the multilayered-reflective-film-provided substrate 110 in Example 4, the multilayered-reflective-film-provided substrate 110 and the reflective mask blank 100 were manufactured in the same manner as in Example 1 except that a third defect inspection different from the first defect inspection and the second defect inspection was performed.

That is, to manufacture the multilayered-reflective-film-provided substrate 110 in Example 4, the multilayered-reflective-film-provided substrate 110 having the third defect information based on the first defect information and the second defect information was manufactured in the same manner as in Example 1. Next, by performing the third defect inspection on this multilayered-reflective-film-provided substrate 110, the multilayered-reflective-film-provided substrate 110 in Example 4 was manufactured.

As a result, the number of first unmatching defects detected only in the first defect inspection was two, the number of second unmatching defects detected only in the second defect inspection was four, and the number of matching defects was five.

For the third defect inspection performed on the multilayered-reflective-film-provided substrate 110 in Example 4, an atomic force microscope (AFM) manufactured by Park systems was used. In the third defect inspection, the defect coordinates and the surface shape of the first unmatching defect (defect detected only in the first defect inspection and not detected in the second defect inspection) were measured. Since the coordinates of the defect center obtained in the first defect inspection were different from the coordinates of the defect center obtained in the third defect inspection, the coordinates obtained in the third defect inspection were used for the coordinates of the first unmatching defect. In the third defect inspection, a reference mark RM (reference mark 20) was used as a reference mark serving as a reference of coordinates.

In this manner, the multilayered-reflective-film-provided substrate 110 in Example 4 having the third defect information based on the first defect information, the second defect information, and the measurement values obtained in the third defect inspection was manufactured.

Next, the reflective mask blank 100 in Example 4 was manufactured in the same manner as in Example 1. The reflective mask blank 100 in Example 4 was used to manufacture the reflective mask 200 in Example 4 in the same manner as in Example 1.

The EUV reflective mask 200 in Example 4 was inspected by a mask defect inspection apparatus (Teron 600 series manufactured by KLA-Tencor Corporation). In this defect inspection, no defect was confirmed in the exposed region of the multilayer reflective film 5 of the absorber pattern 7a.

### Comparative Example 1

To manufacture the multilayered-reflective-film-provided substrate 110 in Comparative example 1, the multilayered-reflective-film-provided substrate 110 was manufactured in the same manner as in Example 1 except that the first defect inspection was not performed. Thus, the multilayered-reflective-film-provided substrate 110 in Comparative Example 1 was the multilayered-reflective-film-provided substrate 110 having only defect information corresponding to the second defect information obtained in the second defect inspection in Example 1. Table 1 shows the number of defects in the second defect inspection in Comparative example 1.

To manufacture the reflective mask blank 100 in Comparative example 1, the reflective mask blank 100 was manufactured in the same manner as in Example 1.

At that time, the eight transfer reference marks RM′ transferred to the absorber film 7 and the eight second reference marks FM (reference marks 24) were measured using a coordinate measuring instrument “LMS-IPRO4” manufactured by KLA-Tencor Corporation that performed coordinate measurement with a laser beam having a wavelength of 365 nm. Based on the relative position coordinates of the transfer reference marks RM′ and the second reference marks FM, the above second defect information was converted into coordinates using the second reference marks FM as a reference to obtain a defect map having defect coordinates.

To manufacture the reflective mask 200 in Comparative example 1, the resist film 8 was formed on the absorber film 7 of the reflective mask blank 100.

Next, a pattern was drawn on the resist film 8 using an electron beam lithography apparatus. When a pattern was drawn, the defect map using the second reference marks FM (reference marks 24) as a reference of defect coordinates was used in order for the defect not to be located in the exposed region of the multilayer reflective film 5 of the absorber pattern 7a. After the pattern was drawn, a predetermined development process was performed to form a resist pattern 8a on the absorber film 7.

Next, the absorber pattern 7a was formed in the same manner as in Example 1 to obtain the reflective mask 200 in Comparative example 1.

The EUV reflective mask 200 in Comparative example 1 was inspected by a mask defect inspection apparatus (Teron 600 series manufactured by KLA-Tencor Corporation). As shown in Table 1, two defects were confirmed in the exposed region of the multilayer reflective film 5 of the absorber pattern 7a in this defect inspection.

From the above, it is obvious that if the multilayered-reflective-film-provided substrate 110 and the reflective mask blank 100 in Examples 1 to 3 of the present embodiment is used, the reflective mask 200 capable of more accurately correcting drawing data based on defect inspection can be manufactured. Thus, by using the multilayered-reflective-film-provided substrate 110 and the reflective mask blank 100 in the present embodiment, it is obvious that it is possible to appropriately apply a technique for correcting drawing data based on defect data and device pattern data in such a manner that the absorber pattern 7a is formed at the position where there is a defect to reduce defects (DM technology).

TABLE 1

| | | | | | Compar- |
|---|---|---|---|---|---|
| | | | | | ative |
| | | Exam- | Exam- | Exam- | exam- |
| | | ple 1 | ple 2 | ple 3 | ple 1 |
| First | First wave- | 355 | 355 | 355 | — |
| defect | length (nm) | | | | |
| inspection | Number of | 3 | 7 | 8 | — |
| | defects | | | | |
| Second | Second wave- | 13.5 | 13.5 | 13.5 | 13.5 |
| defect | length (nm) | | | | |
| inspection | Number of | 8 | 6 | 6 | 6 |
| | defects | | | | |
| Number of unmatching defects | | 1 | 3 | 5 | — |
| (detected only in first defect | | | | | |
| inspection) | | | | | |
| Number of unmatching defects | | 6 | 2 | 3 | — |
| (detected only in second defect | | | | | |
| inspection) | | | | | |
| Number of matching defects | | 2 | 4 | 3 | — |
| Third | Third wave- | — | 193 | — | — |
| defect | length (nm) | | | | |
| inspection | Number of | — | 7 | — | — |
| (Inspection | defects | | | | |
| of multilayer | | | | | |
| reflective | | | | | |
| film) | | | | | |
| Third | Third wave- | — | — | 193 | — |
| defect | length (nm) | | | | |
| inspection | Number of | — | — | 8 | — |
| (Inspection | defects | | | | |
| of absorber | | | | | |
| film) | | | | | |

| | | | | |
|---|---|---|---|---|
| Number of defects in exposed | 0 | 0 | 0 | 2 |
| region of multilayer reflective | | | | |
| film of reflective mask | | | | |

What is claimed is:

1. A method of manufacturing a multilayered-reflective-film-provided substrate including a substrate and a multilayer reflective film that reflects EUV light on the substrate, the method comprising:
performing a first defect inspection on the multilayered-reflective-film-provided substrate with a first wavelength to acquire first defect information;
performing a second defect inspection on the multilayered-reflective-film-provided substrate with a second wavelength different from the first wavelength to acquire second defect information; and
determining whether there is an unmatching defect and a matching defect by comparing the first defect information with the second defect information to acquire third defect information.

2. The method of manufacturing the multilayered-reflective-film-provided substrate according to claim 1, wherein
the second wavelength is a wavelength substantially equal to an exposure wavelength, and
the first wavelength is a wavelength longer than the second wavelength.

3. The method of manufacturing the multilayered-reflective-film-provided substrate according to claim 1, wherein
the multilayered-reflective-film-provided substrate includes a reference mark RM,
the first defect information includes first mark coordinates RM1 of the reference mark RM and first defect coordinates, and
the second defect information includes second mark coordinates RM2 of the reference mark RM and second defect coordinates, and
the acquiring the third defect information is based on converting, based on relative position coordinates of the first mark coordinates RM1 and the second mark coordinates RM2, the first defect coordinates using the first mark coordinates RM1 as a reference into coordinates using the second mark coordinates RM2 as a reference.

4. The method of manufacturing the multilayered-reflective-film-provided substrate according to claim 1, wherein
when there is the unmatching defect between the first defect information and the second defect information, the unmatching defect is used as a defect in a first defect map using the first mark coordinates RM1 as a reference, and
when there is the matching defect between the first defect information and the second defect information, the matching defect is used as a defect in a second defect map using the second mark coordinates RM2 as a reference.

5. The method of manufacturing the multilayered-reflective-film-provided substrate according to claim 1, further comprising:
identifying a first unmatching defect detected only in the first defect inspection and a second unmatching defect detected only in the second defect inspection when there is the unmatching defect between the first defect information and the second defect information; and
performing a third defect inspection different from the first defect inspection and the second defect inspection on the multilayered-reflective-film-provided substrate, wherein
the third defect inspection includes measuring a defect dimension of at least one of the matching defect and the first unmatching defect, and
the defect dimension measured in the third defect inspection is added to the third defect information.

6. The method of manufacturing the multilayered-reflective-film-provided substrate according to claim 1, wherein the multilayered-reflective-film-provided substrate further includes a protective film on the multilayer reflective film.

7. A reflective mask blank comprising:
a multilayered-reflective-film-provided substrate manufactured by the method for manufacturing the multilayered-reflective-film-provided substrate according to claim 1; and
an absorber film formed on the multilayered-reflective-film-provided substrate.

8. The reflective mask blank according to claim 7, wherein the absorber film includes a second reference mark FM formed on the absorber film and a transfer reference mark RM′ obtained by transferring the reference mark RM to the absorber film.

9. A method of manufacturing a reflective mask blank comprising:
identifying a first unmatching defect detected only in the first defect inspection and a second unmatching defect detected only in the second defect inspection when there is the unmatching defect between the first defect information and the second defect information about the reflective mask blank according to claim 7; and
performing a third defect inspection on the reflective mask blank with a third wavelength different from the first wavelength and the second wavelength, wherein
the third defect inspection includes measuring a defect dimension of at least one of the matching defect transferred to the absorber film and the first unmatching defect, and
the defect dimension measured in the third defect inspection is added to the third defect information.

10. A method of manufacturing a reflective mask, comprising patterning the absorber film of the reflective mask blank according to claim 7 to form an absorber pattern.

11. The method of manufacturing the multilayered-reflective-film-provided substrate according to claim 2, wherein
the multilayered-reflective-film-provided substrate includes a reference mark RM,
the first defect information includes first mark coordinates RM1 of the reference mark RM and first defect coordinates, and
the second defect information includes second mark coordinates RM2 of the reference mark RM and second defect coordinates, and
the acquiring the third defect information is based on converting, based on relative position coordinates of the first mark coordinates RM1 and the second mark coordinates RM2, the first defect coordinates using the first mark coordinates RM1 as a reference into coordinates using the second mark coordinates RM2 as a reference.

12. The method of manufacturing the multilayered-reflective-film-provided substrate according to claim 11, wherein
when there is the unmatching defect between the first defect information and the second defect information, the unmatching defect is used as a defect in a first defect map using the first mark coordinates RM1 as a reference, and
when there is the matching defect between the first defect information and the second defect information, the matching defect is used as a defect in a second defect map using the second mark coordinates RM2 as a reference.

13. The method of manufacturing the multilayered-reflective-film-provided substrate according to claim 12, further comprising:
identifying a first unmatching defect detected only in the first defect inspection and a second unmatching defect detected only in the second defect inspection when there is the unmatching defect between the first defect information and the second defect information; and
performing a third defect inspection different from the first defect inspection and the second defect inspection on the multilayered-reflective-film-provided substrate, wherein
the third defect inspection includes measuring a defect dimension of at least one of the matching defect and the first unmatching defect, and
the defect dimension measured in the third defect inspection is added to the third defect information.

14. The method of manufacturing the multilayered-reflective-film-provided substrate according to claim 13, wherein the multilayered-reflective-film-provided substrate further includes a protective film on the multilayer reflective film.

15. A reflective mask blank comprising:
a multilayered-reflective-film-provided substrate manufactured by the method for manufacturing the multilayered-reflective-film-provided substrate according to claim 6; and
an absorber film formed on the multilayered-reflective-film-provided substrate.

16. The reflective mask blank according to claim 15, wherein the absorber film includes a second reference mark FM formed on the absorber film and a transfer reference mark RM′ obtained by transferring the reference mark RM to the absorber film.

17. A method of manufacturing a reflective mask blank comprising:
identifying a first unmatching defect detected only in the first defect inspection and a second unmatching defect detected only in the second defect inspection when there is the unmatching defect between the first defect information and the second defect information about the reflective mask blank according to claim 16; and
performing a third defect inspection on the reflective mask blank with a third wavelength different from the first wavelength and the second wavelength, wherein
the third defect inspection includes measuring a defect dimension of at least one of the matching defect transferred to the absorber film and the first unmatching defect, and
the defect dimension measured in the third defect inspection is added to the third defect information.

18. A method of manufacturing a reflective mask, comprising patterning the absorber film of the reflective mask blank according to claim 16 to form an absorber pattern.

19. A method of manufacturing a reflective mask, comprising patterning a reflective mask blank manufactured by the method for manufacturing a reflective mask blank according to claim 17 to form an absorber pattern.

20. A method of manufacturing a reflective mask, comprising patterning a reflective mask blank manufactured by the method for manufacturing a reflective mask blank according to claim 9 to form an absorber pattern.
